(19) United States
(12) Patent Application Publication
(10) Pub. No.: US 2026/0339590 A1
(43) Pub. Date: Oct. 29, 2026

(54) DISPLAY DEVICE

(71) Applicant: FD IP & LICENSING LLC, Los Angeles, CA (US)

(72) Inventors: Brandon FAYETTE, Los Angeles, CA (US); Simcha Jakob BOHUSLAV, San Francisco, CA (US)

(21) Appl. No.: 19/685,395

(22) Filed: May 22, 2026

Related U.S. Application Data
(63) Continuation of application No. PCT/US2026/025374, filed on Apr. 27, 2026.
(60) Provisional application No. 63/794,666, filed on Apr. 25, 2025.

(51) Int. Cl. G06F 3/14; H04N 5/222; H05K 5/02

(52) U.S. Cl. CPC G06F 3/1423; H04N 5/2222; H05K 5/0204

(57) ABSTRACT

A display system comprising a computing system and one or more display devices. Each display device includes a housing having a central opening. Each display device also includes a display screen disposed within the central opening of the housing and configured to render graphical content. Each display device further includes a controller disposed within the housing and communicatively connected to the display screen. The computing system is communicatively connected to each of the display devices and is configured to transmit graphical content to each respective display screen via the respective controller of each display device. The display system is used within a production environment for producing films.

### FIELD OF THE DISCLOSURE

The present disclosure relates generally to systems for filmmaking and, more particularly, to a display device for use with filmmaking technology.

### BACKGROUND OF THE DISCLOSURE

Filmmaking and other similar production environments have historically required numerous discrete tools for on set communication and instruction. The recent development of improved filmmaking technologies continues to add capabilities lacking in existing production equipment. There remains a need for improved production equipment that is able to leverage the improved filmmaking technologies while simplifying the complex production environment.

### SUMMARY OF THE DISCLOSURE

Various details of the present disclosure are hereinafter summarized to provide a basic understanding. This summary is not an exhaustive overview of the disclosure and is neither intended to identify certain elements of the disclosure, nor to delineate the scope thereof. Rather, the primary purpose of this summary is to present some concepts of the disclosure in a simplified form prior to the more detailed description that is presented hereinafter.

According to an embodiment consistent with the present disclosure, a display device includes a housing having a central opening. The display devices include a display screen disposed within the central opening of the housing and configured to render graphical content. The display device includes a controller disposed within the housing and configured to provide the graphical content to the display screen. The display device further includes at least one mount disposed on the housing and configured to mechanically couple the display device to production mounting equipment in a production environment.

In another embodiment, a display system includes a computing system. The display system also includes one or more display devices, each display device including a housing having a central opening. The display device also includes a display screen disposed within the central opening of the housing and configured to render graphical content. The display device further includes a controller disposed within the housing and communicatively connected to the display screen. The computing system is communicatively connected to each of the display devices and is configured to transmit graphical content to each respective display screen via the respective controller of each display device.

In a further embodiment, a method of deploying a display system in a production environment includes positioning at least one display device at a desired location within the production environment. Each display device includes a housing having a central opening, a display screen disposed within the central opening, and a controller disposed within the housing and communicatively connected to the display screen. The method includes establishing a communicative connection between a computing system and each of the at least one display device. The method also includes generating, at the computing system, graphical content. The method further includes transmitting the graphical content from the computing system to each of the at least one display device via the communicative connection, such that the controller of each display device drives the respective display screen to render the graphical content.

Any combinations of the various embodiments and implementations disclosed herein can be used in a further embodiment, consistent with the disclosure. These and other aspects and features can be appreciated from the following description of certain embodiments presented herein in accordance with the disclosure and the accompanying drawings and claims.

### BRIEF DESCRIPTION OF THE DRAWINGS

FIG. 1 is an isometric front view of a display device showing the display screen, housing, and mounts.

FIG. 2 is an isometric view of the display device.

FIG. 3 is a front elevation view of the display device showing the display screen rendering a facial representation as graphical content.

FIG. 4 is a rear elevation view of the display device.

FIG. 5 is a top view of the display device.

FIG. 6 is a bottom view of the display devic.

FIG. 7 is a left side view of the display device showing the housing.

FIG. 8 is a right side view of the display device showing the housing.

FIG. 9 is a front view of the front cover illustrating the screen diameter and the front diameter defining the area of the front face.

FIG. 10 is a rear isometric view of the front cover illustrating the housing diameter, front threads, and port slot.

FIG. 11 is a rear isometric view of the back cover.

FIG. 12 is another rear isometric view of the back cover.

FIG. 13 is a front isometric view of the internal support.

FIG. 14 is a rear isometric view of the internal.

FIG. 15 is a front view of the internal support.

FIG. 16 is a rear view of the internal support.

FIG. 17 is an isometric view of the display screen and controller of the display device.

FIG. 18 is a front isometric view of the display device in a partially assembled state.

FIG. 19 is a rear isometric view of the display device in a partially assembled state.

FIG. 20 is a block diagram of the display device illustrating the functional architecture of the controller and its communicative connections to the display screen, wireless communication system, video ports, and power/data ports.

FIG. 21 is a block diagram of a display system including a computing system and a plurality of display devices.

FIG. 22 is a flowchart illustrating a method of deploying the display system in a production environment.

FIG. 23 is a block diagram of a computer system that may be used to implement one or more of the systems or methods described herein in accordance with certain embodiments.

### DETAILED DESCRIPTION

Embodiments of the present disclosure will now be described in detail with reference to the accompanying drawing figures. Like elements in the various figures may be denoted by like reference numerals. Further, in the following detailed description, specific details are set forth in order to provide a more thorough understanding of the claimed subject matter. However, it will be apparent to one of ordinary skill in the art that the embodiments disclosed herein may be practiced without these specific details, or with details that are not described herein in the interest of clarity. Thus in some instances, well-known features have not been described in detail to avoid unnecessarily complicating the description. Additionally, it will be apparent to one of ordinary skill in the art that the scale of the elements presented in the accompanying drawing figures may vary without departing from the scope of the present disclosure.

Embodiments in accordance with the present disclosure generally relate to systems for filmmaking, and more particularly to a display device for use with filmmaking technology. The display device is a compact, self-contained display unit configured for use in professional filmmaking and production environments. The display device is designed to serve as a multi-functional tool on a production set, capable of operating as an eyeline tool, a teleprompter, a visual effects (VFX) tracking tool, a direction aid, or a combination thereof. By consolidating these functions into a single device, the display device reduces the number of discrete tools required on set, thereby simplifying the production environment and improving operational efficiency. The display device includes a display screen housed within a housing that is configured for flexible mounting in a variety of positions and orientations around a production set. The housing is further configured to accommodate control circuitry, power circuitry, and communication systems that enable the display device to receive and display content from connected computing systems, whether by wired or wireless connection. The compact and modular nature of the display device allows it to be readily repositioned, reconfigured, and redeployed across different production scenarios without requiring specialized installation or dedicated infrastructure.

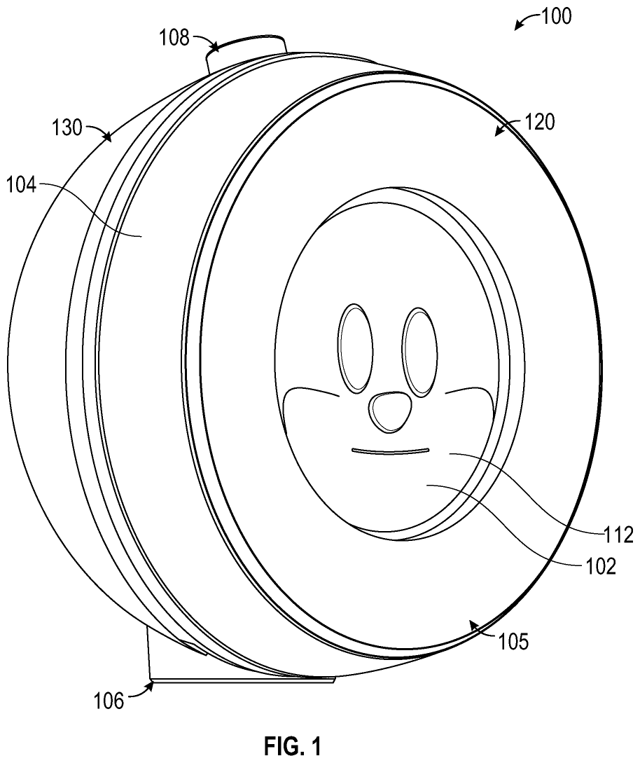

FIG. 1 illustrates a display device 100 in accordance with the present disclosure. The display device 100 includes a display screen 102 and a housing 104. The display screen 102 is disposed on a front face 105 of the housing 104 and is visible from the front of the display device 100. The display screen 102 may be a light-emitting diode (LED) display, an organic light-emitting diode (OLED) display, a liquid crystal display (LCD), or any other suitable display technology. The housing 104 has a generally toroidal or annular outer profile, presenting a circular form factor that surrounds the display screen 102. The circular form factor of the housing 104 is well-suited to production environments in which the display device 100 is positioned in proximity to a camera lens, as the shape does not impose a preferred orientation and may be viewed from a wide range of angles. The housing 104 is configured to enclose and protect the internal components of the display device 100, including the display screen 102, control circuitry, and power circuitry. A first mount 106 is provided at a lower portion of the housing 104. The first mount 106 is configured to mechanically couple the display device 100 to external mounting equipment, such as a tripod, camera rig, or other standard production mounting hardware, thereby allowing the display device 100 to be positioned and secured at a desired location on a production set. A second mount 108 is provided at an upper portion of the housing 104, opposite the first mount 106, providing an additional mounting point and enabling the display device 100 to be mounted from either direction as required by the production configuration. The display screen 102 is configured to render graphical content 112, which may include images, video, animations, text, symbols, or any combination thereof transmitted to the display device 100 from a connected computing system, as described in further detail herein. The display device 100 is further composed of multiple components not limited to a front cover 120 and a back cover 130, as discussed in further detail herein.

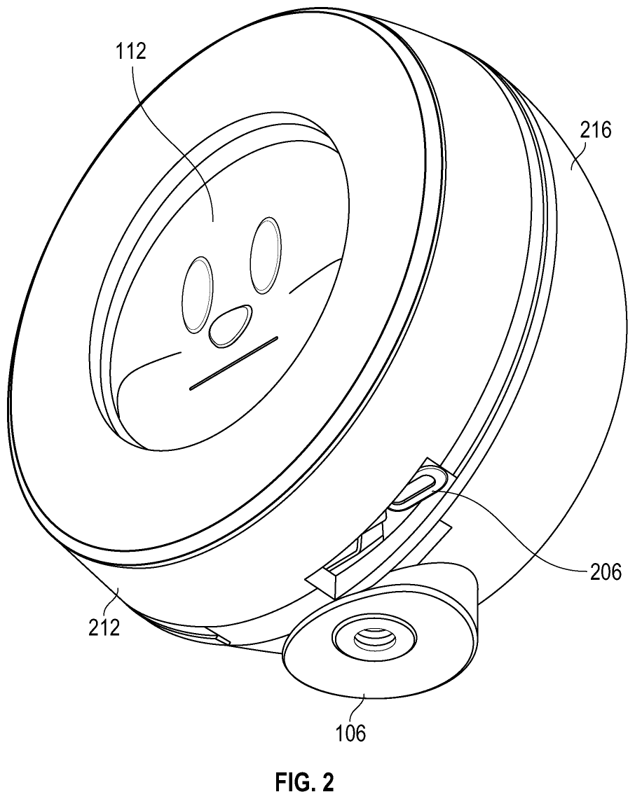

FIG. 2 illustrates an isometric view of the display device 100, showing a front perspective of the housing 104. As shown in FIG. 2, the housing 104 includes a first mount 106 disposed at a lower portion thereof. The first mount 106 comprises a threaded female end configured to receive a complementary threaded fastener, such as a standard camera mounting screw or tripod bolt, thereby enabling the display device 100 to be mechanically coupled to a wide variety of production mounting equipment including tripods, camera rigs, articulating arms, and other standard mounting hardware. The threaded female configuration of the first mount 106 provides a secure and repeatable mechanical connection that resists inadvertent decoupling during use on a production set. A universal serial bus (USB) port 206 is disposed on the housing 104 proximal to the first mount 106. The USB port 206 is configured to provide a wired connection for power delivery, data transfer, or both, enabling the display device 100 to be connected to external power sources or computing systems as required by the production configuration. The proximity of the USB port 206 to the first mount 106 facilitates cable management when the display device 100 is mounted on production equipment, as both the mounting connection and the wired power or data connection may be made at the same region of the housing 104.

Also visible in FIG. 2 is the outer profile of the housing 104, which includes a front outer surface 212 and a rear outer surface 216. The front cover 120 includes the front outer surface 212 and the back cover 130 includes the rear outer surface 216. The front outer surface 212 is the outward-facing circumferential surface of the housing 104 that connects the front face 105 to the remainder of the housing 104, forming the peripheral wall of the annular housing 104 as seen from the front. The rear outer surface 216 is the corresponding circumferential surface on the opposing side of the housing 104, connecting the back face of the housing 104 to the remainder of the annular structure. Together, the front outer surface 212 and the rear outer surface 216 define the depth profile of the housing 104 and bound the internal volume within which the display screen 102, control circuitry, and power circuitry are enclosed. The USB port 206 is disposed on the front outer surface 212, proximal to the first mount 106, such that wired connections to the display device 100 may be made at the front outer surface 212 without requiring access to the back face of the housing 104.

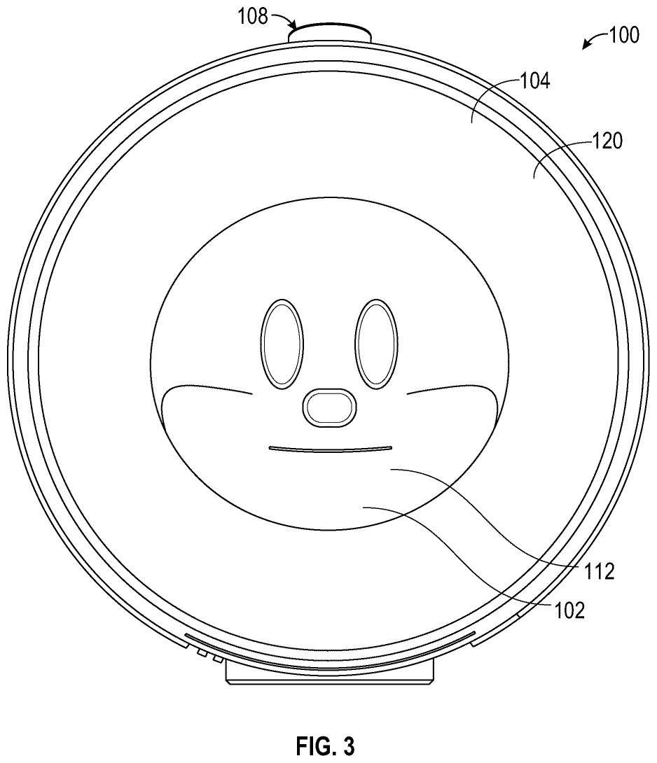

FIG. 3 illustrates a front elevation view of the display device 100, showing the display screen 102 as viewed directly from the front of the housing 104. As shown in FIG. 3, the display screen 102 occupies a substantial portion of the front face of the housing 104 and is bounded by the annular profile of the housing 104. The second mount 108 is visible at an upper portion of the housing 104, and the first mount 106 is visible at a lower portion of the housing 104, consistent with the arrangement described with respect to FIG. 1. In the embodiment illustrated in FIG. 3, the display screen 102 is shown rendering graphical content 112 in the form of a stylized character face comprising eyes, a nose, and a mouth. The ability of the display screen 102 to render graphical content 112 depicting a facial representation is particularly advantageous in filmmaking applications in which an actor is required to perform a scene opposite a computer-generated character or an off-camera performer. In such applications, the display device 100 may be positioned proximate to a camera lens so that the graphical content 112 rendered on the display screen 102 falls within the actor's natural line of sight during performance. By providing a visible facial reference at or near the camera axis, the display device 100 enables the actor to direct their gaze and emotional response toward a specific point corresponding to the position of the computer-generated character or absent performer, thereby producing more naturalistic and consistent eyeline in the captured footage. The graphical content 112 may be static or animated, and may be updated in real time by the connected computing system to reflect changes in the character's expression, gaze direction, or position as required by the production. The circular form factor of the housing 104 further facilitates this application, as the display screen 102 may be positioned concentrically around a camera lens without obstructing the camera's field of view, allowing the actor's performance to be captured simultaneously with the display of the graphical content 112.

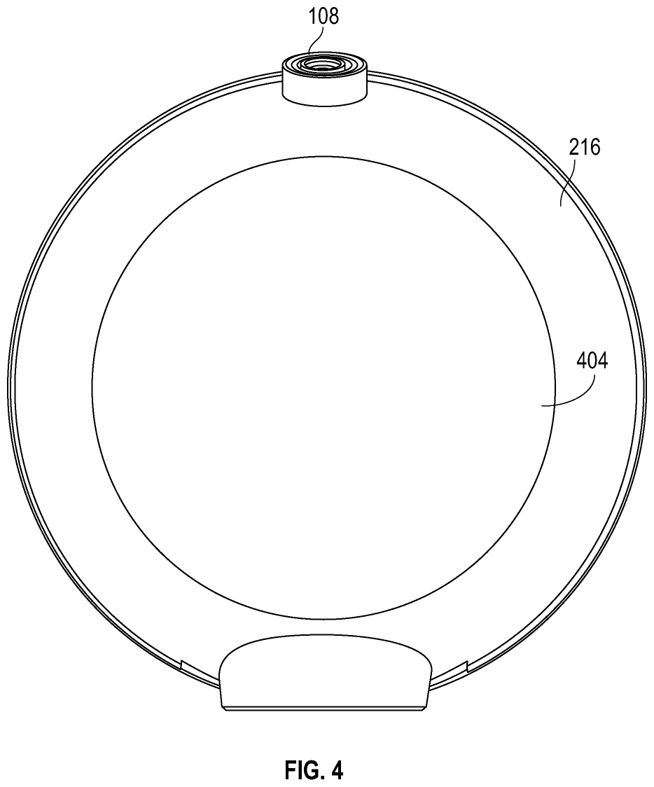

FIG. 4 illustrates a rear view of the display device 100, showing the back face 404 of the housing 104. As shown in FIG. 4, the annular profile of the housing 104 is visible from the back face 404, with the second mount 108 disposed at an upper portion of the housing 104 and the first mount 106 disposed at a lower portion of the housing 104, consistent with the arrangement described with respect to FIGS. 1 and 3. The back face 404 of the housing 104 encloses the internal components of the display device 100, including the control circuitry and power circuitry, and presents a substantially planar surface bounded by the annular outer wall of the housing 104. The third mounting point 109 is also visible in this view, disposed on the back face 404 of the housing 104. The third mounting point 109 provides an additional point of mechanical attachment, enabling the display device 100 to be secured to a wider variety of mounting configurations and production equipment than would be possible with the first mount 106 and second mount 108 alone. The provision of multiple mounting points distributed about the housing 104 allows the display device 100 to be oriented and secured in a range of positions on a production set, including horizontal, vertical, and angled orientations, without compromising the stability of the mechanical connection. The view of FIG. 4 further illustrates the depth profile of the housing 104, which is configured to be sufficiently compact to permit the display device 100 to be positioned in close proximity to a camera lens or other production equipment without introducing undue obstruction or interference with the surrounding production environment.

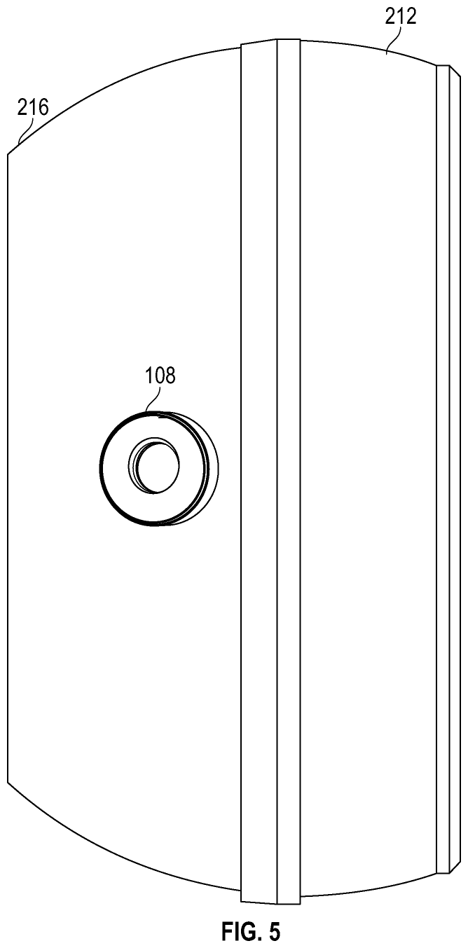

FIG. 5 illustrates a top view of the display device 100, showing the housing 104 as viewed from above. As shown in FIG. 5, the depth profile of the housing 104 is visible in this orientation, with the front outer surface 212 and the rear outer surface 216 bounding the annular housing 104 on either side. The front outer surface 212 is visible at the forward-facing side of the housing 104, and the rear outer surface 216 is visible at the rearward-facing side, together defining the overall depth of the housing 104 as seen from above. The second mount 108 is visible at the upper portion of the housing 104 in this view, projecting outwardly from the annular wall of the housing 104 and providing a point of mechanical attachment accessible from above. The top view of FIG. 5 further illustrates the relationship between the front outer surface 212 and the rear outer surface 216, showing how the two circumferential surfaces are separated by the internal volume of the housing 104 within which the display screen 102, control circuitry, and power circuitry are enclosed. The top view of FIG. 5 illustrates the compact depth profile of the housing 104, which is configured to permit the display device 100 to be positioned in close proximity to a camera lens or other production equipment without introducing undue obstruction to the surrounding production environment.

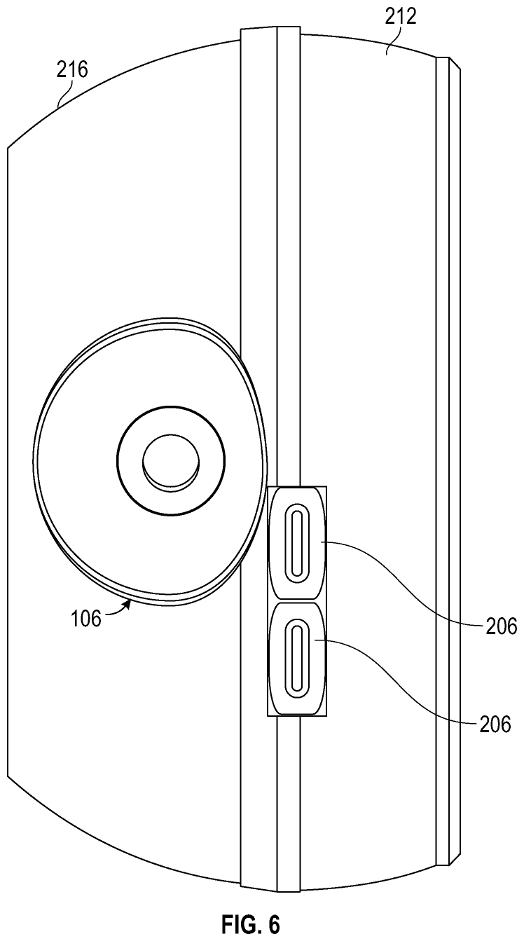

FIG. 6 illustrates a bottom view of the display device 100, showing the housing 104 as viewed from below. As shown in FIG. 6, the first mount 106 is visible at the lower portion of the housing 104 in this orientation, projecting downwardly from the annular wall of the housing 104 and providing a point of mechanical attachment accessible from below. The bottom view of FIG. 6 further illustrates the front outer surface 212, along which the USB port 206 is disposed proximal to the first mount 106. The positioning of the USB port 206 on the front outer surface 212 at the lower region of the housing 104, in proximity to the first mount 106, is particularly advantageous in mounted configurations, as wired power or data cables connected to the USB port 206 may be routed directly alongside the mounting hardware connected to the first mount 106, thereby minimizing cable exposure and reducing the risk of cable interference with the surrounding production environment. The bottom view of FIG. 6 also illustrates the depth profile of the housing 104 as defined by the front outer surface 212 and the rear outer surface 216, consistent with the arrangement described with respect to FIGS. 2 and 5. The compact depth profile of the housing 104 is further apparent in this view, confirming that the display device 100 is configured to be positioned in close proximity to a camera lens or other production equipment without introducing undue obstruction.

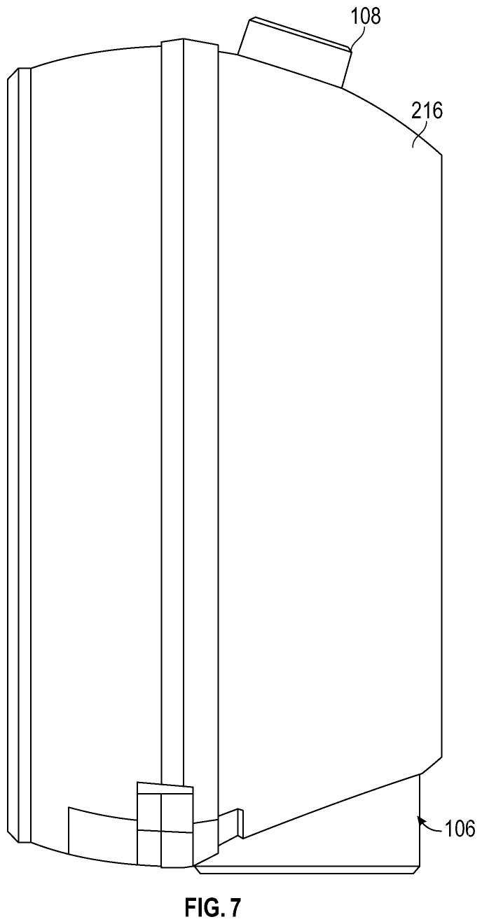

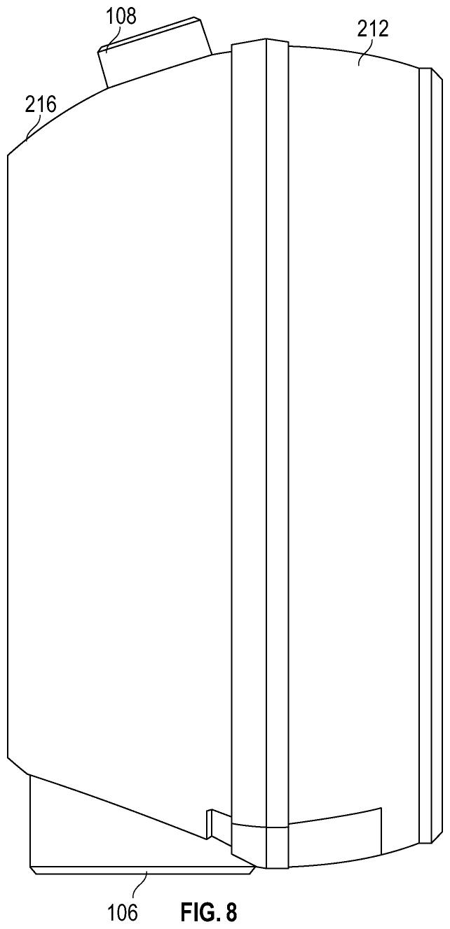

FIGS. 7 and 8 illustrate left and right side views of the display device 100, respectively. These views further illustrate the outer profile of the housing 104, including the front outer surface 212 and the rear outer surface 216, as well as the relative positions of the first mount 106 and the second mount 108, consistent with the arrangements described with respect to the preceding figures.

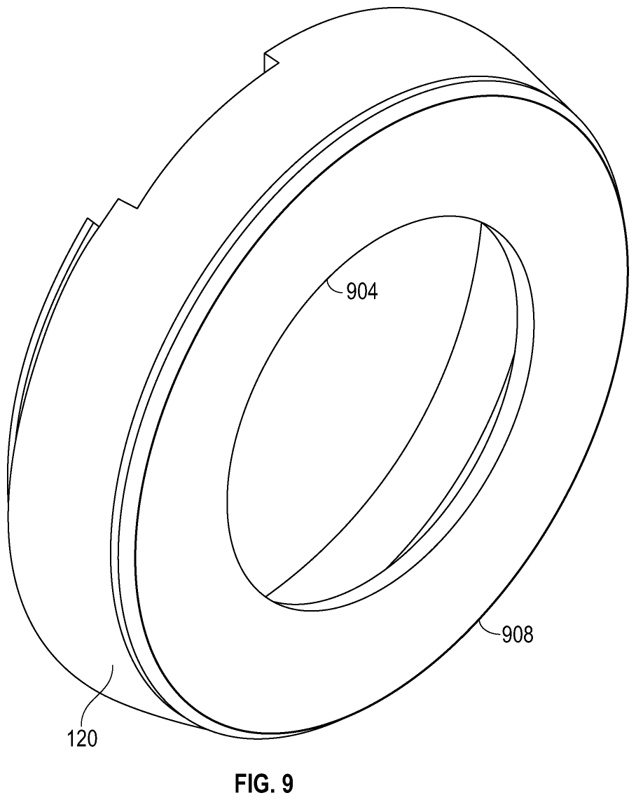

FIG. 9 illustrates a front view of the front cover 120 of the display device 100. As shown in FIG. 9, the front cover 120 presents an annular profile defining the front face 105 of the housing 104. The dimensions illustrated in FIG. 9 includes a screen diameter 904 and a front diameter 908. The front diameter 908 defines the overall outer diameter of the front face 105 of the front cover 120, corresponding to the outermost circular boundary of the annular front cover 120 as viewed from the front. The screen diameter 904 defines the diameter of a central opening formed through the front cover 120, through which the display screen 102 is visible when the display device 100 is fully assembled. The central opening defined by the screen diameter 904 is sized to expose the active display area of the display screen 102 to the viewer, while the annular region of the front cover 120 between the screen diameter 904 and the front diameter 908 forms the visible front face 105 of the housing 104 surrounding the display screen 102. Together, the screen diameter 904 and the front diameter 908 define the area of the front face 105, with the screen diameter 904 establishing the inner boundary and the front diameter 908 establishing the outer boundary of the annular front face 105. The relative proportions of the screen diameter 904 and the front diameter 908 may be selected to maximize the active display area of the display screen 102 while maintaining sufficient structural integrity in the front cover 120 to protect the internal components of the display device 100.

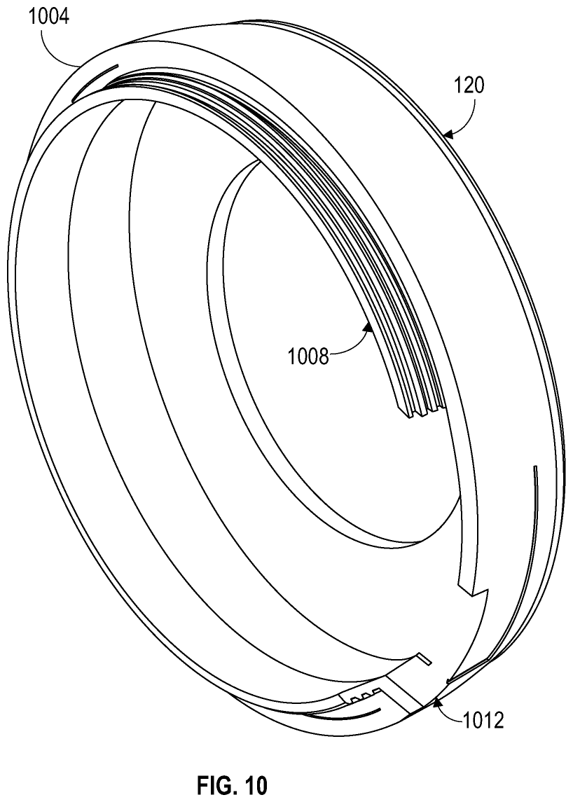

FIG. 10 illustrates a rear isometric view of the front cover 120, showing the internal-facing side of the front cover 120 as it would be oriented during assembly of the display device 100. As shown in FIG. 10, the front cover 120 includes a housing diameter 1004, which represents the overall outer diameter of the assembled housing 104. The housing diameter 1004 thus defines the outermost circular boundary of the display device 100 as a whole, and the front cover 120 is dimensioned accordingly so that the front cover 120, when assembled with the back cover 130, presents a continuous and uniform outer profile at the housing diameter 1004. The rear-facing side of the front cover 120 further includes front threads 1008 disposed on an inner circumferential surface of the front cover 120. The front threads 1008 are configured to engage with complementary threads on the back cover 130, thereby providing a threaded mechanical connection between the front cover 120 and the back cover 130 that secures the two components together to form the housing 104. The threaded connection provided by the front threads 1008 enables the front cover 120 to be removably secured to the back cover 130, facilitating access to the internal components of the display device 100 for assembly, maintenance, or replacement as required. Also visible in FIG. 10 is a port slot 1012 formed through the front cover 120. The port slot 1012 is configured to receive and expose the USB port 206 disposed on the front outer surface 212 of the housing 104, allowing a wired connection to be made to the USB port 206 through the front cover 120 without requiring removal of the front cover 120. The port slot 1012 is positioned on the front cover 120 at a location corresponding to the position of the USB port 206 on the assembled housing 104, enabling alignment between the port slot 1012 and the USB port 206 when the front cover 120 is secured to the back cover 130.

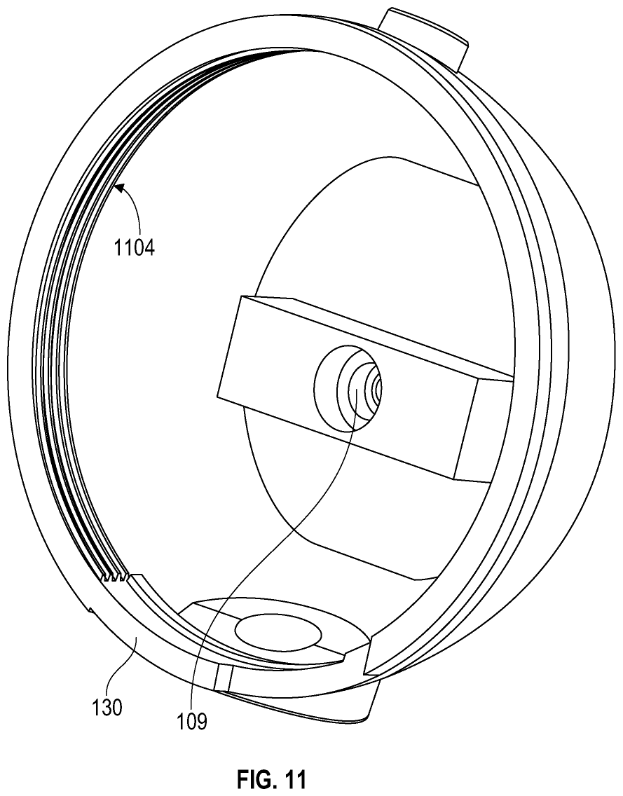

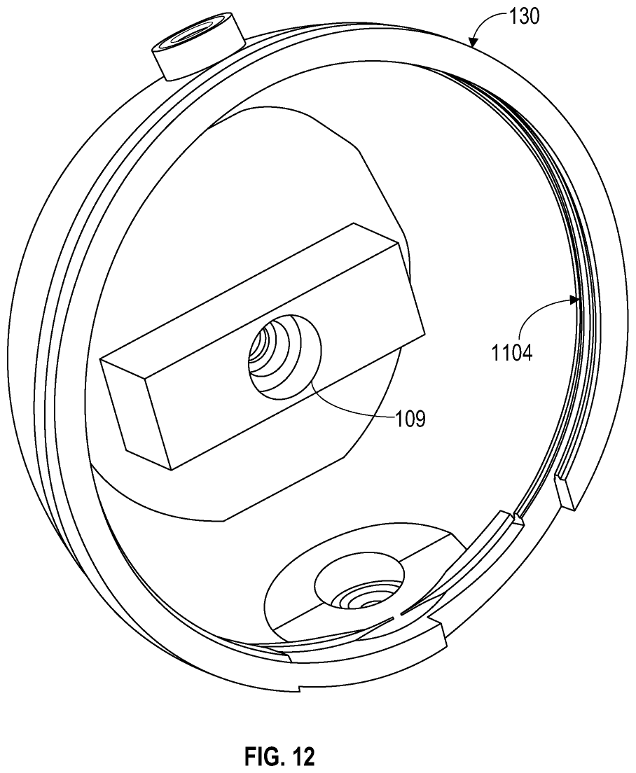

FIGS. 11 and 12 illustrate views of the back cover 130 of the display device 100, showing the rear-facing side of the back cover 130 as it would be oriented during assembly. As shown in FIGS. 11 and 12, the back cover 130 presents an annular profile corresponding to the overall form factor of the housing 104, with the first mount 106 disposed at a lower portion of the back cover 130 and the second mount 108 disposed at an upper portion, consistent with the arrangements described with respect to the preceding figures. The back cover 130 includes back threads 1104 disposed on an inner circumferential surface of the back cover 130. The back threads 1104 are configured to engage with the front threads 1008 of the front cover 120, thereby forming the threaded mechanical connection between the front cover 120 and the back cover 130 that secures the two components together to form the assembled housing 104. The engagement of the back threads 1104 with the front threads 1008 provides a removable and repeatable connection that permits the front cover 120 to be separated from the back cover 130 to access the internal components of the display device 100 for assembly, maintenance, or replacement as required. The back cover 130 is further dimensioned at the housing diameter 1004 so that, when assembled with the front cover 120, the back cover 130 presents a continuous and uniform outer profile consistent with the overall outer boundary of the display device 100. The third mounting point 109 is also visible in these views, disposed on the back cover 130 and providing an additional point of mechanical attachment for securing the display device 100 to production mounting equipment.

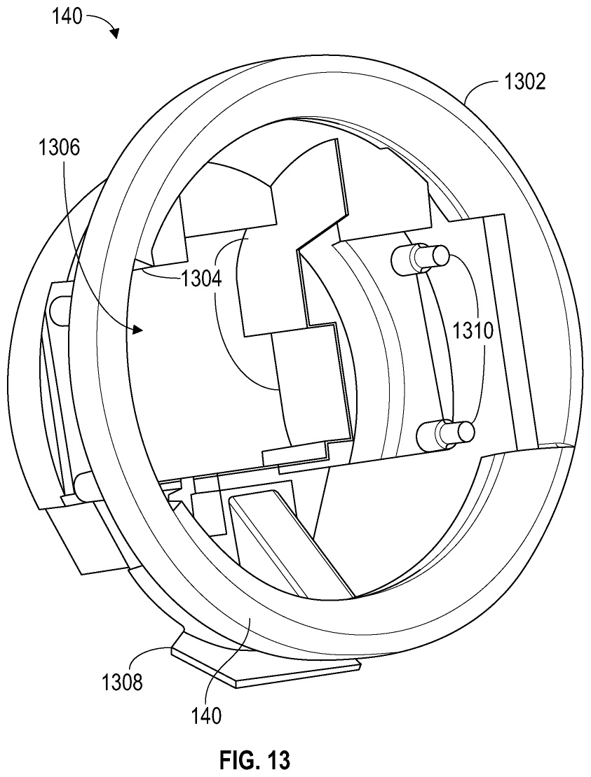

FIG. 13 illustrates a front isometric view of the internal support 140 of the display device 100. The internal support 140 is a structural component disposed within the housing 104 and configured to support the display screen 102, the controller 150, and associated power and control circuitry in a fixed and stable position within the internal volume of the housing 104. The internal support 140 is dimensioned to fit within the annular interior of the housing 104 and is configured to be retained between the front cover 120 and the back cover 130 when the housing 104 is fully assembled. As shown in FIG. 13, the internal support 140 presents a generally frame-like structure comprising an outer ring 1302 and a plurality of inwardly extending structural members 1304 that collectively define a central mounting region 1306 within which the display screen 102 and controller 150 may be secured. A base foot 1308 is disposed at a lower portion of the internal support 140, providing a stable resting surface when the display device 100 is placed on a flat surface and further serving as a locating feature during assembly of the housing 104. A plurality of locating features 1310 are distributed about the outer ring 1302 of the internal support 140 and are configured to engage with complementary features on the interior surfaces the internal support 140 within the assembled housing 104. The locating features 1310 further resist relative rotation or displacement of the internal support 140 within the housing 104 during use, maintaining the positional integrity of the display screen 102 and controller 150 in all mounting orientations. The locating features 1310 are further employed to receive and secure the controller 150 between the front cover 120 and back cover 130.

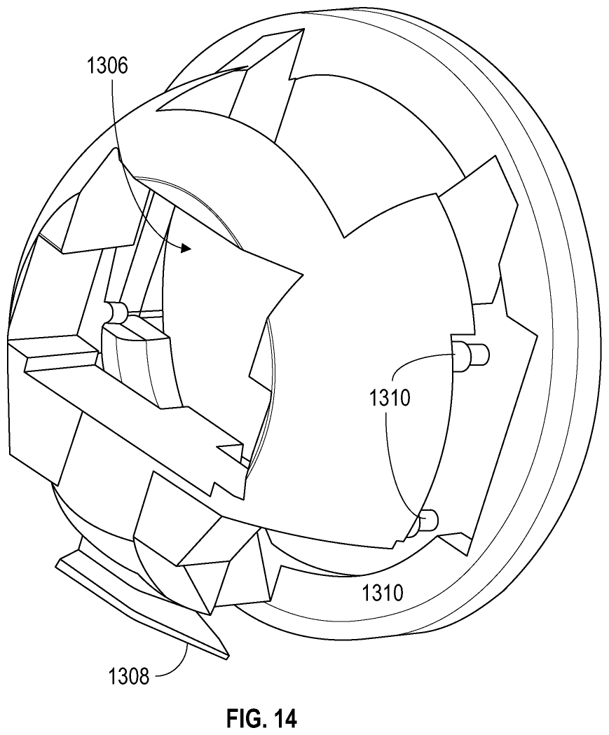

FIG. 14 illustrates a rear isometric view of the internal support 140, showing the rearward-facing side of the frame-like structure as it would be oriented during assembly of the display device 100. As shown in FIG. 14, the arrangement of the outer ring 1302, the inwardly extending structural members 1304, and the central mounting region 1306 is further visible from the rear, confirming the symmetrical and rigid nature of the internal support 140. The rear isometric view of FIG. 14 illustrates that the internal support 140 provides a rigid and stable platform for the internal components of the display device 100 while remaining accessible from the rear of the housing 104 when the back cover 130 is removed. The base foot 1308 is also visible in this view at the lower portion of the internal support 140, consistent with its position as described with respect to FIG. 13. The locating features 1310 distributed about the outer ring 1302 are further visible in this view, illustrating their distribution about the circumference of the outer ring 1302 to provide balanced engagement with the interior surfaces of the front cover 120 and back cover 130.

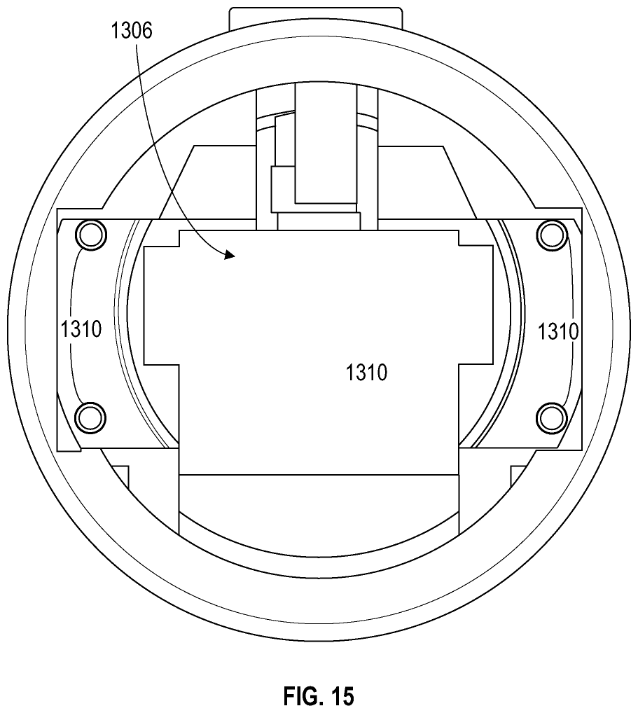

FIG. 15 illustrates a front view of the internal support 140, showing the arrangement of the outer ring 1302, the inwardly extending structural members 1304, and the central mounting region 1306 as viewed directly from the front. As shown in FIG. 15, the outer ring 1302 of the internal support 140 is dimensioned at a diameter corresponding to the interior of the housing 104, and the structural members 1304 extend inwardly from the outer ring 1302 to define the central mounting region 1306. The central mounting region 1306 is configured to receive and retain the display screen 102 and the controller 150 in a fixed position relative to the housing 104. The second mount 108 is visible at the upper portion of the internal support 140 in this view, projecting outwardly from the outer ring 1302 and providing a point of mechanical attachment that is accessible through the assembled housing 104. The locating features 1310 are also visible in this view, distributed about the outer ring 1302 at positions configured to align with complementary features on the interior surfaces of the front cover 120 and back cover 130.

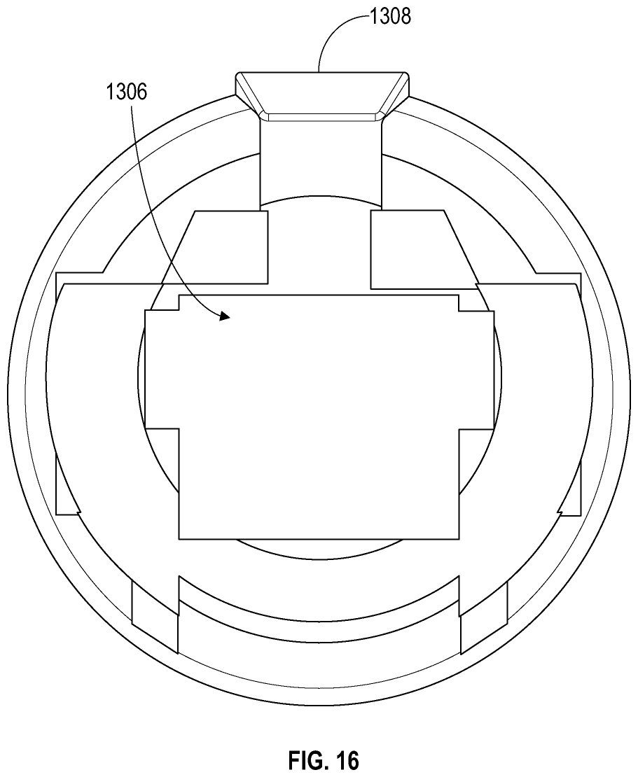

FIG. 16 illustrates a rear view of the internal support 140, showing the rearward-facing side of the frame structure as viewed directly from the rear. As shown in FIG. 16, the outer ring 1302, the inwardly extending structural members 1304, and the central mounting region 1306 are visible in this orientation, consistent with the arrangements described with respect to FIGS. 13-15. The rear view of FIG. 16 further illustrates the relationship between the internal support 140 and the second mount 108 at the upper portion of the outer ring 1302, confirming that the second mount 108 projects outwardly from the outer ring 1302 and is accessible from the exterior of the assembled housing 104. Together, FIGS. 13-16 illustrate that the internal support 140 provides a self-contained structural subassembly that organizes and retains the internal components of the display device 100 within the housing 104, facilitating assembly and disassembly of the display device 100 while maintaining the positional integrity of the display screen 102 and controller 150 during use.

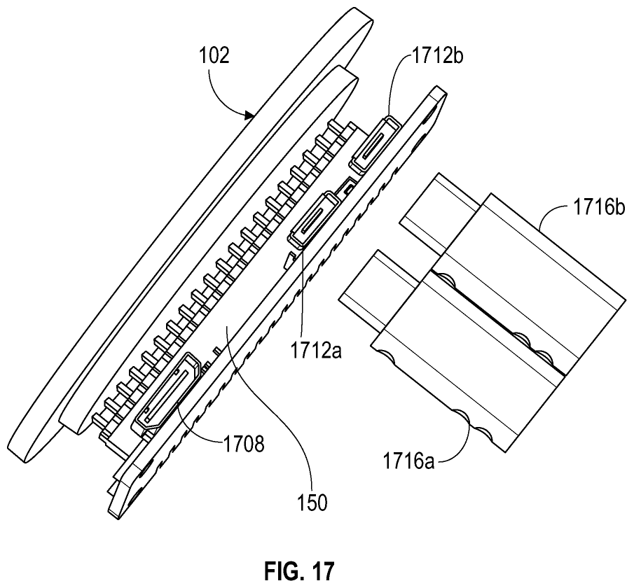

FIG. 17 illustrates the display screen 102 and the controller 150 of the display device 100, showing the two principal electronic subassemblies of the display device 100 as they would be oriented during assembly within the central mounting region 1306 of the internal support 140. As shown in FIG. 17, the display screen 102 is embodied as a circular panel dimensioned to fit within the central mounting region 1306, with a plurality of electrical connection points disposed about its periphery for communicative connection to the controller 150. The controller 150 is a control circuitry assembly configured to drive the display screen 102 and to manage all input, output, power, and communication functions of the display device 100. In one embodiment, the controller 150 may be a single board computer, the compact form factor of which reduces both the power consumption and the spatial requirements of the control circuitry, thereby enabling the controller 150 to be accommodated within the internal volume of the annular housing 104 without compromising the compact depth profile of the display device 100. The controller 150 is communicatively connected to the display screen 102 and is configured to transmit graphical content 112 to the display screen 102 for rendering in response to signals received from connected computing systems. As shown in FIG. 17, the display device 100 includes a plurality of wired connectivity ports, including a first USB-C port 1712a, a second USB-C port 1712b, and high-definition multimedia interface (HDMI) port 1708. The first USB-C port 1712a and the second USB-C port 1712b are configured to provide wired connections for power delivery, data transfer, or both, enabling the display device 100 to receive power from an external power source or to exchange data with an external computing system as required by the production configuration. In one embodiment, the first USB-C port 1712a may be dedicated to power delivery while the second USB-C port 1712b is dedicated to data transfer, though other configurations are also contemplated.

It will be appreciated that the first USB-C port 1712a and the second USB-C port 1712b, as illustrated in FIG. 17, are internal connectivity ports of the controller 150 and may be distinct from the USB port 206 exposed on the front outer surface 212 of the housing 104 as described with respect to FIG. 2, the latter serving as the externally accessible wired connection point of the assembled display device 100. To bridge the physical separation between the internal connectivity ports of the controller 150 and the externally exposed USB port 206, the display device 100 includes a first USB extender 1716a and a second USB extender 1716b. The first USB extender 1716a is configured to couple to the first USB-C port 1712a of the controller 150 and to extend the physical reach of the first USB-C port 1712a to the USB port 206 on the front outer surface 212 of the housing 104. Similarly, the second USB extender 1716b is configured to couple to the second USB-C port 1712b of the controller 150 and to extend the physical reach of the second USB-C port 1712b to the USB port 206. The first USB extender 1716a and the second USB extender 1716b thus provide a continuous wired connectivity pathway from the internal controller 150 to the externally accessible USB port 206, enabling external power and data connections to be made at the front outer surface 212 of the housing 104 without requiring direct access to the internal ports of the controller 150. The HDMI port 1708 is configured to receive a video signal from an external computing system, providing an alternative wired video input pathway to the controller 150 and the display screen 102. The controller 150 may further include, or be communicatively connected to, a wireless communication system configured to transmit and receive signals to and from external devices. The wireless communication system may operate in accordance with any available wireless communication standard, including Bluetooth, WiFi, or wireless display protocols such as Apple® AirPlay, thereby enabling the display device 100 to receive graphical content 112 from a smartphone, tablet, laptop, or other computing system without requiring a wired connection. The provision of both wired and wireless connectivity options enables the display device 100 to be integrated into a wide variety of production workflows and technical environments. In embodiments in which a wired power supply is unavailable or impractical, the display device 100 may be powered by an internal power supply, such as a replaceable or rechargeable battery retained within the internal volume of the housing 104, enabling the display device 100 to operate as a fully self-contained and portable unit on a production set.

In embodiments, the display device 100 includes one or more ports for power and/or data connections. As shown in FIG. 6, the display device 100 may include two ports for connecting to external equipment. In one example, the display device includes one USB-C port for power and a second USB-C port for data connection. In other embodiments, the display device may include an HDMI port. Other numbers and types of ports may also be included to provide wired connections as desired.

Referring now to FIGS. 9-16, the housing 104 may be a multi-part structure. In one embodiment, the housing 104 includes a front cover 120 (such as shown in FIGS. 9-10) and a back cover 130 (such as shown in FIGS. 11-12). The front cover 120 may have a threaded connection to be secured to the back cover 130 thereby forming the housing 104. The front cover 120 may also include an opening through which the display screen 102 is visible. The back cover 130 may include a threaded connection for receiving the front cover, and may also include one or more features for mounting the display screen, control circuitry, power circuitry or other components within the housing.

The housing 104 may also include an internal support 140 configured to support one or more of the display screens, control circuity, power circuitry, or other components within the housing. The internal support 140 may form separately from the front cover and back cover. Alternatively, the internal support 140 may be integrally formed with either cover as desired for ease of assembly.

As shown in FIG. 17, the display device 100 includes a display screen 102 controlled by control circuitry, such as controller 150. The controller 150 may be communicatively connected to the one or more ports as previously discussed. As shown in FIG. 17, the display device may have two USB-C ports and one HDMI port. In one embodiment, the controller 150 may be a single board computer to reduce power and space requirements. The controller 150 may also include, or be connected to, a wireless communication system (Tx/Rx). The wireless communication system may enable wireless communication with other devices such as smartphones, tables, or other computers using any available standards such as Bluetooth, WiFi or the Apple® Airplay technology. The display device 100 may have an internal power supply, such as a replaceable or rechargeable battery. The display device 100 may also be capable of receiving a wired power supply, such as through one of the USB-C ports.

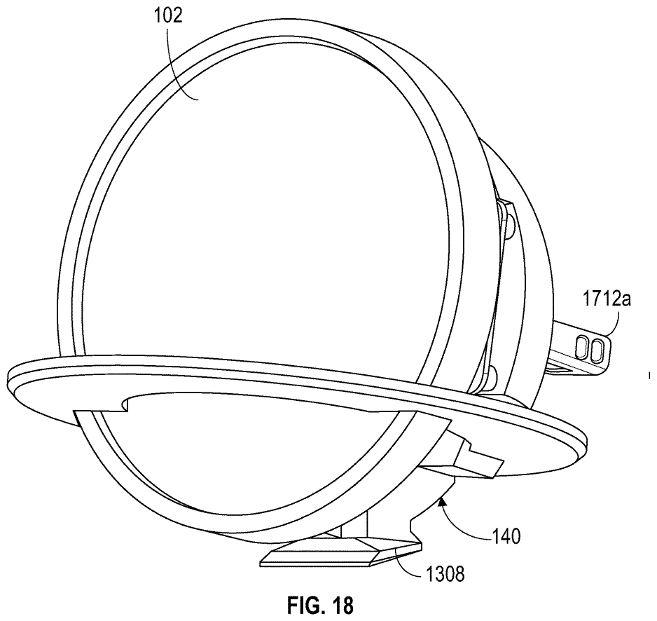

FIG. 18 illustrates a front isometric view of the display device 100 in a partially assembled state, showing the internal subassembly of the display device 100 prior to enclosure within the housing 104. As shown in FIG. 18, the internal support 140 is visible in this orientation, with the outer ring 1302 bounding the frame-like structure and the inwardly extending structural members 1304 defining the central mounting region 1306. The display screen 102 is shown seated within the central mounting region 1306 of the internal support 140, with its front face directed forwardly and its peripheral electrical connection points engaged with the controller 150 retained immediately behind it within the central mounting region 1306. The base foot 1308 is disposed at the lower portion of the internal support 140, consistent with the arrangement described with respect to FIG. 13, and the second mount 108 is visible projecting outwardly from the upper portion of the outer ring 1302. The locating features 1310 are distributed about the outer ring 1302, configured to engage with complementary features on the interior surfaces of the housing 104 upon final assembly. The partially assembled view of FIG. 18 illustrates how the internal support 140 organizes the display screen 102 and the controller 150 into a self-contained subassembly, facilitating assembly of the display device 100 and ensuring accurate and repeatable positioning of the display screen 102 and controller 150 relative to the housing 104 when the housing 104 is closed.

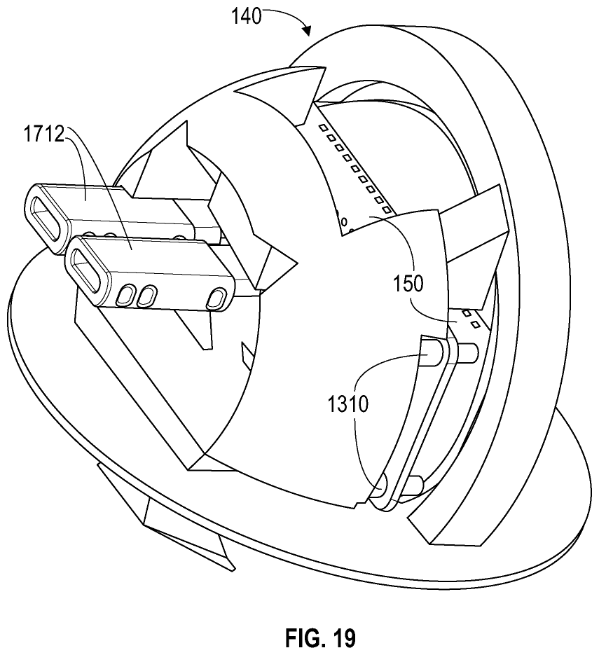

FIG. 19 illustrates a rear isometric view of the display device 100 in a partially assembled state, showing the rearward-facing side of the internal subassembly prior to enclosure within the housing 104. As shown in FIG. 19, the controller 150 is visible within the central mounting region 1306 of the internal support 140, retained by the inwardly extending structural members 1304 and positioned immediately behind the display screen 102. The first USB extender 1716a and the second USB extender 1716b are visible in this view, each coupled to their respective first USB-C port 1712a and second USB-C port 1712b on the controller 150 and routed outwardly from the central mounting region 1306 toward the front outer surface 212 of the housing 104, providing the wired connectivity pathway to the externally exposed USB port 206 upon final assembly. The HDMI port 1708 is also visible in this view, accessible at the periphery of the controller 150 within the central mounting region 1306. The locating features 1310 distributed about the outer ring 1302 of the internal support 140 are visible in this view, illustrating their outward-facing positions about the circumference of the outer ring 1302 and confirming their configuration for engagement with complementary features on the interior surfaces of the housing 104 upon assembly. The rear isometric view of FIG. 19 further illustrates the spatial relationship between the controller 150, the internal support 140, and the associated connectivity components, confirming that all wired connectivity is organized and routed within the internal subassembly prior to enclosure, such that the USB port 206 on the front outer surface 212 is accessible via the first USB extender 1716a and the second USB extender 1716b once the housing 104 is fully assembled.

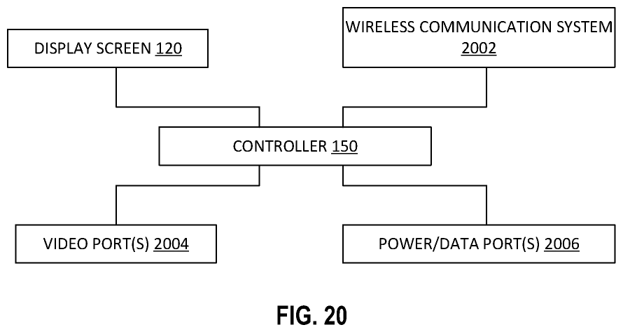

FIG. 20 illustrates a block diagram of the display device 100, showing the functional architecture of the controller 150 and its communicative connections to the principal subsystems of the display device 100. As shown in FIG. 20, the controller 150 is the central processing and control node of the display device 100, and is communicatively connected to four functional subsystems: the display screen 102, a wireless communication system 2002 (Tx/Rx), one or more video ports 2004, and one or more power/data ports 2006. The display screen 102, as described with respect to FIGS. 1, 3, and 17, is driven by the controller 150 to render graphical content 112 in response to signals received from connected computing systems. The wireless communication system 2002, denoted Tx/Rx in FIG. 20, corresponds to the wireless communication system described with respect to FIG. 17, and is configured to transmit and receive signals to and from external devices in accordance with available wireless communication standards, including Bluetooth, WiFi, or wireless display protocols such as Apple® AirPlay. The one or more video ports 2004 correspond to wired video input connections to the controller 150 and may include or correspond to the HDMI port 1708 described with respect to FIG. 17, and are configured to receive a video signal from an external computing system for transmission to the display screen 102 via the controller 150. The one or more power/data ports 2006 provide wired connections for power delivery, data transfer, or both, and may include or correspond to the externally accessible USB port 206 described with respect to FIGS. 2 and 6, as routed from the first USB-C port 1712a and the second USB-C port 1712b of the controller 150 via the first USB extender 1716a and the second USB extender 1716b described with respect to FIGS. 17 and 19. The block diagram of FIG. 20 illustrates that the controller 150 serves as the central hub through which all display output, wireless communication, wired video input, and wired power and data connectivity of the display device 100 are managed, enabling the display device 100 to receive graphical content 112 from a wide variety of external sources and to render that content on the display screen 102 in a flexible and production-ready manner.

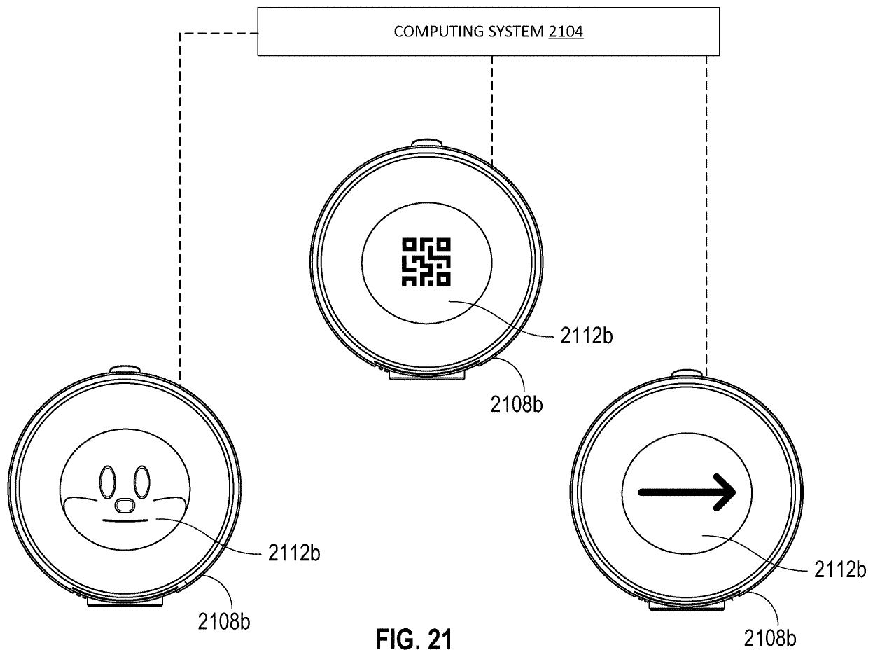

FIG. 21 illustrates a block diagram of a display system 2100 in accordance with the present disclosure, showing an embodiment in which a plurality of display devices are deployed together under the control of a common computing system. As shown in FIG. 21, the display system 2100 comprises a computing system 2104 communicatively connected to a plurality of display devices 2108a-n, where n is an integer greater than one, each of the plurality of display devices 2108a-n including a respective display screen 2112a-n. The computing system 2104 may be communicatively connected to and/or may control each of the plurality of display devices 2108a-n by any available wired or wireless means. In embodiments, the computing system 2104 may be or may include a previsualization system such as disclosed in U.S. Pat. No. 11,682,175, a system for animating computer generated images such as disclosed in U.S. Pat. No. 12,254,551, a system for real-time segmentation and tracking of objects such as disclosed in U.S. patent application Ser. No. 19/045,228, or a system for determining camera parameters such as disclosed in U.S. patent application Ser. No. 19/045,239, or any combination thereof, the disclosures of which are incorporated by reference. The computing system 2104 is configured to transmit graphical content 112 to each of the plurality of display devices 2108a-n, either individually or collectively, via wired connections through the respective power/data ports 2006 or video ports 2004 of each display device, or wirelessly via the respective wireless communication systems 2002 of each display device, as described with respect to FIGS. 17 and 20. Each of the plurality of display devices 2108a-n is independently addressable by the computing system 2104, such that the computing system 2104 may transmit different graphical content 112 to each respective display screen 2112a-n simultaneously, or may transmit the same graphical content 112 to all display devices 2108a-n in a synchronized manner, depending on the requirements of the production. The computing system 2104 may further update the graphical content 112 transmitted to any or all of the plurality of display devices 2108a-n in real time, enabling the display system 2100 to respond dynamically to changes in the production workflow without requiring physical access to any individual display device.

In a first embodiment of the display system 2100, the display system 2100 is configured to operate as an eyeline tool. In this embodiment, the graphical content 112 transmitted by the computing system 2104 and rendered on one or more of the display screens 2112a-n comprises a representation of one or more eyes, oriented and positioned to assist an actor with visualizing the gaze direction, emotional state, or spatial position of another actor or computer-generated character that is absent from the physical production set. The graphical content 112 may depict a pair of eyes, a single eye, or a stylized facial representation, and may be rendered as a static image or as an animated sequence in which the depicted eyes move, blink, shift gaze direction, or otherwise respond dynamically to the requirements of the scene. In embodiments in which the graphical content 112 is animated, the controller 150 of each respective display device 2108a-n may receive real-time signals from the computing system 2104, such as a previsualization system or a character animation system, and update the graphical content 112 rendered on the respective display screen 2112a-n in response to those signals, such that the depicted eyes reflect the live or pre-programmed behavior of the computer-generated character during the performance. Each display device 2108a-n may be positioned concentrically around a camera lens so that the graphical content 112 depicting the eyes is presented at or near the camera axis, enabling the actor to direct their gaze toward the display screen 2112a-n while simultaneously being captured by the camera, thereby producing naturalistic and consistent eyeline in the resulting footage without requiring the actor to look away from the camera. In embodiments in which the computer-generated character is of a scale or proportion that requires the eyes to be spatially separated, two display devices 2108a and 2108b of the display system 2100 may be deployed simultaneously, with the display screen 2112a of the first display device 2108a rendering graphical content 112 corresponding to a first eye of the character and the display screen 2112b of the second display device 2108b rendering graphical content 112 corresponding to a second eye of the character, such that the spatial separation between the two display devices 2108a and 2108b replicates the interpupillary distance or eye spacing of the character as it would appear in the scene. The graphical content 112 rendered in the eyeline tool embodiment may further include gaze direction indicators, pupil position variations, or other visual cues configured to guide the actor's performance and ensure consistency of eyeline across multiple takes or camera angles. The ability of the computing system 2104 to update the graphical content 112 transmitted to the display devices 2108a-n in real time enables the eyeline tool embodiment to respond dynamically to changes in the character's animation, the camera position, or the director's instructions during the course of a take, without requiring interruption of the production workflow.

In a second embodiment of the display system 2100, the display system 2100 is configured to operate as a teleprompter. In this embodiment, the graphical content 112 transmitted by the computing system 2104 and rendered on one or more of the display screens 2112a-n comprises text, script lines, cue cards, or other written content configured to assist an actor, presenter, or other on-camera talent in delivering spoken dialogue or narration without requiring the talent to look away from the camera. The graphical content 112 may be rendered as scrolling text that advances at a rate corresponding to the pace of the talent's delivery, or as static text blocks that are advanced manually or automatically by an operator using the computing system 2104. The controller 150 of each respective display device 2108a-n receives the graphical content 112 from the computing system 2104 via the wireless communication system 2002 or via the one or more power/data ports 2006 or video ports 2004, and transmits the graphical content 112 to the respective display screen 2112a-n for rendering in real time. The circular form factor of the housing 104 of each display device 2108a-n and the positioning of the display screen 102 within the central opening defined by the screen diameter 904 enable each display device 2108a-n to be mounted concentrically around a camera lens, such that the graphical content 112 is presented within the talent's natural line of sight while the camera captures the talent's performance along the same optical axis. This arrangement enables the talent to read the graphical content 112 rendered on the display screen 2112a-n while maintaining a gaze direction that is substantially aligned with the camera lens, producing footage in which the talent appears to be speaking directly to the viewer rather than reading from an off-axis source. The graphical content 112 rendered in the teleprompter embodiment may further include formatting elements such as font size, line spacing, highlighting, or color coding configured to improve legibility on the display screen 2112a-n at the distances and lighting conditions typical of a production set. The scrolling speed, font size, and content of the graphical content 112 may be adjusted in real time by an operator using the computing system 2104 communicating with the controller 150 of each respective display device 2108a-n via the wireless communication system 2002, enabling the teleprompter operation to be managed remotely without requiring physical access to any display device during a take. The ability of the same display system 2100 to function as both an eyeline tool and a teleprompter, by virtue of the computing system 2104 transmitting different graphical content 112 to the display screens 2112a-n in each application, reduces the number of discrete tools required on a production set and enables rapid reconfiguration between applications without requiring any physical modification to any of the display devices 2108a-n.

In a third embodiment of the display system 2100, the display system 2100 is configured to operate as a visual effects (VFX) tracking tool, such as a lighthouse system. In this embodiment, the graphical content 112 transmitted by the computing system 2104 and rendered on each of the display screens 2112a-n comprises a unique visual marker, such as a quick response (QR) code, a fiducial marker, a geometric pattern, or any other machine-readable symbol configured to be detected and identified by the image sensors of one or more cameras or previsualization devices present on the production set. The graphical content 112 rendered in this embodiment is configured to be visually distinctive and unambiguous, such that each display device 2108a-n deployed on the production set may be individually identified by the computing system 2104 based on the specific graphical content 112 rendered on its respective display screen 2112a-n. The controller 150 of each respective display device 2108a-n receives the graphical content 112 comprising the unique marker from the computing system 2104 via the wireless communication system 2002 or via the one or more power/data ports 2006, and renders the graphical content 112 on the respective display screen 2112a-n such that the marker is visible to the image sensors of surrounding cameras and devices. As explained in U.S. Pat. No. 11,682,175, a camera tracking module of the computing system 2104 may triangulate the position and orientation of each camera and previsualization device on the production set based on video signals received from multiple devices in real time, using each display device 2108a-n as a spatial anchor. In some embodiments, the spatial anchor may be a virtual anchor. The graphical content 112 rendered on each display screen 2112a-n thus serves as a physical reference point within the production environment, enabling the computing system 2104 to establish and maintain a shared coordinate system across all devices on the set. Without such spatial anchors, each device would maintain its own independent view of the positions and orientations of computer-generated imagery (CGI) assets, such that any change or repositioning made on one device would not necessarily be reflected consistently on other devices. By rendering the graphical content 112 comprising the unique marker on each display screen 2112a-n, the display system 2100 enables a shared view of the position and rotation of objects across all connected devices, ensuring that CGI assets are consistently positioned and oriented relative to the physical production environment in real time. The graphical content 112 rendered in the VFX tracking tool embodiment may be updated by the computing system 2104 as required, for example to change the identity of the marker rendered on any of the display screens 2112a-n or to modify the appearance of the marker to improve detectability under the lighting conditions present on the production set. The circular form factor of the housing 104 of each display device 2108a-n and the multiple mounting points provided by the first mount 106, the second mount 108, and the third mounting point 109 enable each display device 2108a-n to be positioned and oriented at a wide variety of locations on the production set, maximizing the visibility of the graphical content 112 to the image sensors of surrounding cameras and devices and thereby improving the accuracy and reliability of the spatial tracking system.

In a fourth embodiment of the display system 2100, the display system 2100 is configured to operate as a direction aid. In this embodiment, the graphical content 112 transmitted by the computing system 2104 and rendered on one or more of the display screens 2112a-n comprises visual indicators, symbols, text, or color-coded signals configured to communicate instructions, directions, or status information to personnel on a production set or in any other environment in which clear and immediate visual communication is required. The graphical content 112 rendered in the direction aid embodiment may include stop indications, rendered as a red symbol, color field, or text, and go indications, rendered as a green symbol, color field, or text, enabling the display system 2100 to function as a visible cue system for coordinating the actions of cast, crew, or other personnel across a production set. The graphical content 112 may further comprise directional arrows, waypoint indicators, positional markers, or other navigational symbols configured to guide personnel to specific locations or orientations on the set, or to indicate the direction of movement required for a particular scene or production activity. In embodiments in which the direction aid application is used to coordinate complex multi-person or multi-unit productions, the computing system 2104 may distribute different directional or status graphical content 112 to different display devices 2108a-n positioned at different locations across a production set, enabling coordinated visual communication to multiple groups of personnel simultaneously, and may update the graphical content 112 transmitted to any or all of the display devices 2108a-n in real time via the wireless communication system 2002, enabling the instructions or indicators rendered on the respective display screens 2112a-n to be changed instantaneously in response to the evolving requirements of the production without requiring physical access to any display device. The graphical content 112 rendered in the direction aid embodiment may also include alphanumeric text, such as scene numbers, take numbers, unit identifiers, or other production-specific information, enabling the display system 2100 to serve simultaneously as a direction aid and an information display within the production environment. The large and clearly visible display screens 2112a-n, each bounded by the annular housing 104 of the respective display device 2108a-n and viewable from a wide range of angles by virtue of the circular form factor of the housing 104, enable the graphical content 112 rendered in the direction aid embodiment to be perceived by multiple individuals simultaneously across a production set, reducing the need for verbal communication and improving the speed and reliability of on-set coordination. It will be appreciated that the direction aid embodiment, and the other embodiments of the display system 2100 described herein, are not limited to the filmmaking environment, and that the display system 2100 may be deployed in any environment in which it is desirable to communicate text, symbols, color-coded signals, or other graphical content 112 to one or more individuals in a clear, flexible, and remotely controllable manner. The display system 2100 thus provides a scalable and flexible multi-device display architecture that extends the capabilities of the individual display device 100 described with respect to FIGS. 1-20 to encompass coordinated multi-device production scenarios of varying scale and complexity.

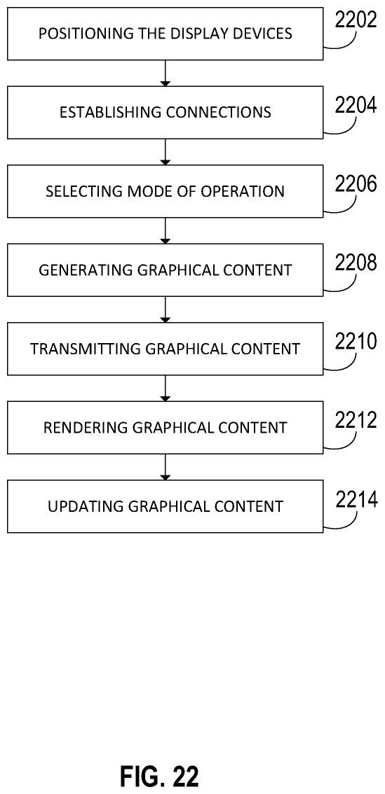

In view of the structural and functional features described above, example methods will be better appreciated with reference to FIGS. 1-21. While, for purposes of simplicity of explanation, the example methods of FIG. 22 is shown and described as executing serially, it is to be understood and appreciated that the present examples are not limited by the illustrated order, as some actions could in other examples occur in different orders, multiple times and/or concurrently from that shown and described herein. Moreover, it is not necessary that all described actions be performed to implement the methods, and conversely, some actions may be performed that are omitted from the description.

FIG. 22 illustrates a method 2200 of deploying the display system 2100 in a production environment in accordance with the present disclosure. The method 2200 may be performed using the display system 2100 described with respect to FIG. 21, comprising the computing system 2104 and the plurality of display devices 2108a-n, each including a respective display screen 2112a-n. The method 2200 begins at step 2202, which comprises positioning one or more of the plurality of display devices 2108a-n at one or more desired locations within the production environment. The positioning of each display device 2108a-n may be accomplished by mechanically coupling the display device 2108a-n to production mounting equipment via the first mount 106, the second mount 108, the third mounting point 109, or any combination thereof, as described with respect to FIGS. 1-4, such that each display device 2108a-n is secured at a location and orientation appropriate to the intended application. In embodiments in which the display system 2100 is to be deployed as an eyeline tool or a teleprompter, one or more of the display devices 2108a-n may be positioned concentrically around a camera lens at step 2202, such that the respective display screen 2112a-n is presented at or near the camera axis. In embodiments in which the display system 2100 is to be deployed as a VFX tracking tool, the display devices 2108a-n may be distributed at a plurality of spatially separated locations across the production set at step 2202, so as to maximize the visibility of the graphical content 112 rendered on each respective display screen 2112a-n to the image sensors of surrounding cameras and previsualization devices.

At step 2204, the method 2200 comprises establishing a communicative connection between the computing system 2104 and each of the plurality of display devices 2108a-n positioned at step 2202. The communicative connection may be established by any available wired or wireless means, including via the one or more power/data ports 2006 or video ports 2004 of each display device 2108a-n, or wirelessly via the respective wireless communication system 2002 of each display device 2108a-n, as described with respect to FIGS. 17 and 20. In embodiments in which a wired connection is established, a wired cable may be connected to the USB port 206 on the front outer surface 212 of the housing 104 of each display device 2108a-n, as described with respect to FIGS. 2 and 6. In embodiments in which a wireless connection is established, the wireless communication system 2002 of each display device 2108a-n may be paired with the computing system 2104 in accordance with any available wireless communication standard, including Bluetooth, WiFi, or a wireless display protocol such as Apple® AirPlay. At step 2206, the method 2200 comprises selecting, at the computing system 2104, a mode of operation for the display system 2100. The mode of operation may be selected from among the eyeline tool embodiment, the teleprompter embodiment, the VFX tracking tool embodiment, and the direction aid embodiment described with respect to FIG. 21, or any combination thereof. The selection of the mode of operation at step 2206 determines the nature of the graphical content 112 that the computing system 2104 will generate and transmit to the plurality of display devices 2108a-n in the subsequent steps of the method 2200.

At step 2208, the method 2200 comprises generating, at the computing system 2104, graphical content 112 appropriate to the mode of operation selected at step 2206. In the eyeline tool mode, the graphical content 112 generated at step 2208 comprises a representation of one or more eyes, a stylized facial representation, gaze direction indicators, pupil position variations, or other visual cues configured to assist an actor with visualizing the gaze direction, emotional state, or spatial position of a computer-generated character or absent performer, as described with respect to FIG. 21. In the teleprompter mode, the graphical content 112 generated at step 2208 comprises text, script lines, cue cards, or other written content, formatted with appropriate font size, line spacing, highlighting, or color coding as required by the production, as described with respect to FIG. 21. In the VFX tracking tool mode, the graphical content 112 generated at step 2208 comprises a unique visual marker, such as a QR code, a fiducial marker, or a geometric pattern, configured to be detected and identified by the image sensors of one or more cameras or previsualization devices on the production set, as described with respect to FIG. 21. In the direction aid mode, the graphical content 112 generated at step 2208 comprises visual indicators, symbols, color-coded signals, directional arrows, waypoint indicators, alphanumeric text, or other content configured to communicate instructions, directions, or status information to personnel on the production set, as described with respect to FIG. 21. In embodiments in which the computing system 2104 is or includes a previsualization system, a character animation system, a real-time segmentation and tracking system, or a camera parameter determination system as described with respect to FIG. 21, the graphical content 112 generated at step 2208 may be derived directly from the output of such systems, enabling the graphical content 112 to reflect the live or pre-programmed state of the production in real time.

At step 2210, the method 2200 comprises transmitting the graphical content 112 generated at step 2208 from the computing system 2104 to one or more of the plurality of display devices 2108a-n via the communicative connection established at step 2204. The computing system 2104 may transmit the same graphical content 112 to all of the display devices 2108a-n simultaneously in a synchronized manner, or may transmit different graphical content 112 to each respective display device 2108a-n individually, depending on the requirements of the production and the mode of operation selected at step 2206. In the eyeline tool mode, for example, the computing system 2104 may transmit graphical content 112 corresponding to a first eye of a computer-generated character to a first display device 2108a and graphical content 112 corresponding to a second eye of the character to a second display device 2108b at step 2210, such that the spatial separation between the two display devices 2108a and 2108b replicates the interpupillary distance of the character as described with respect to FIG. 21. In the VFX tracking tool mode, the computing system 2104 may transmit a unique visual marker as graphical content 112 to each of the display devices 2108a-n individually at step 2210, such that each display device 2108a-n renders a distinct marker on its respective display screen 2112a-n to serve as a uniquely identifiable spatial anchor within the production environment. At step 2212, the method 2200 comprises rendering, at each of the one or more display devices 2108a-n, the graphical content 112 received at step 2210 on the respective display screen 2112a-n. The controller 150 of each display device 2108a-n receives the graphical content 112 transmitted by the computing system 2104 and drives the display screen 2112a-n to render the graphical content 112 in real time, as described with respect to FIGS. 17 and 20.

At step 2214, the method 2200 comprises updating, at the computing system 2104, the graphical content 112 transmitted to one or more of the plurality of display devices 2108a-n in response to a change in the production workflow, a change in the mode of operation, or an instruction received from an operator. The update performed at step 2214 may comprise modifying the graphical content 112 transmitted to any or all of the display devices 2108a-n in real time via the communicative connection established at step 2204, without requiring physical access to any individual display device 2108a-n and without interrupting the operation of the display system 2100. In the eyeline tool mode, the update at step 2214 may comprise transmitting revised graphical content 112 reflecting a change in the computer-generated character's animation, gaze direction, or expression in response to real-time signals received from a previsualization system or character animation system. In the teleprompter mode, the update at step 2214 may comprise adjusting the scrolling speed, font size, or content of the graphical content 112 rendered on one or more of the display screens 2112a-n in response to an instruction from an operator using the computing system 2104 via the wireless communication system 2002. In the VFX tracking tool mode, the update at step 2214 may comprise transmitting revised graphical content 112 comprising a modified or replacement visual marker to one or more of the display devices 2108a-n to improve the detectability of the marker under changed lighting conditions on the production set. In the direction aid mode, the update at step 2214 may comprise transmitting revised graphical content 112 comprising updated directional indicators, color-coded signals, or alphanumeric text to one or more of the display devices 2108a-n in response to a change in the production schedule, scene requirements, or on-set coordination needs. The method 2200 thus provides a flexible and scalable procedure for deploying the display system 2100 across a wide variety of production applications, enabling the computing system 2104 to manage the graphical content 112 rendered across all of the plurality of display devices 2108a-n in a coordinated, real-time, and remotely controllable manner throughout the course of a production.

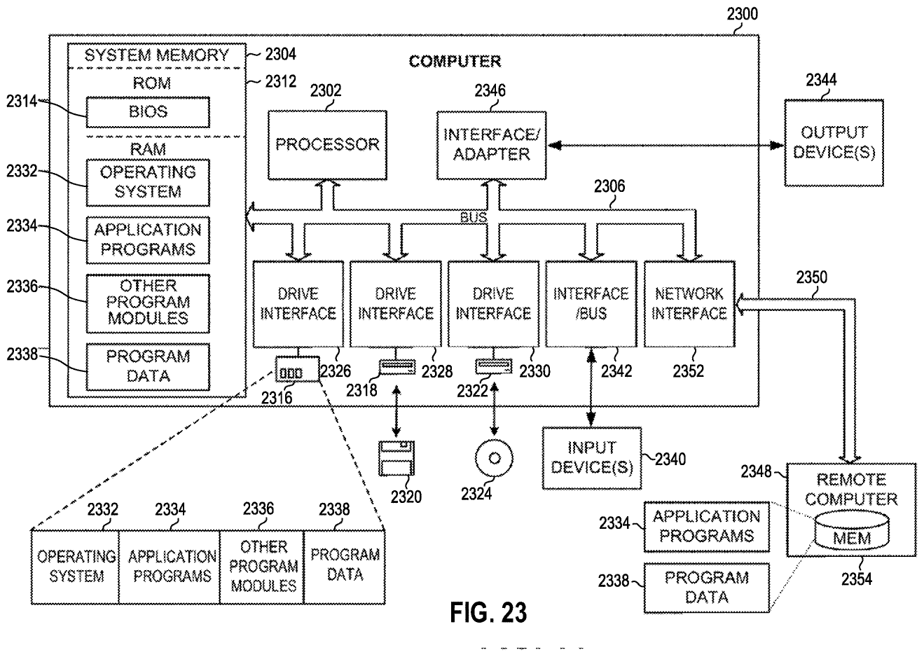

In view of the foregoing structural and functional description, those skilled in the art will appreciate that portions of the embodiments may be embodied as a method, data processing system, or computer program product. Accordingly, these portions of the present embodiments may take the form of an entirely hardware embodiment, an entirely software embodiment, or an embodiment combining software and hardware, such as shown and described with respect to the computer system of FIG. 23. Furthermore, portions of the embodiments may be a computer program product on a computer-readable storage medium having computer readable program code on the medium. Any non-transitory, tangible storage media possessing structure may be utilized including, but not limited to, static and dynamic storage devices, volatile and non-volatile memories, hard disks, optical storage devices, and magnetic storage devices, but excludes any medium that is not eligible for patent protection under 35 U.S.C. § 101 (such as a propagating electrical or electromagnetic signals per se). As an example and not by way of limitation, computer-readable storage media may include a semiconductor-based circuit or device or other IC (such, as for example, a field-programmable gate array (FPGA) or an ASIC), a hard disk, an HDD, a hybrid hard drive (HHD), an optical disc, an optical disc drive (ODD), a magneto-optical disc, a magneto-optical drive, a floppy disk, a floppy disk drive (FDD), magnetic tape, a holographic storage medium, a solid-state drive (SSD), a RAM-drive, a SECURE DIGITAL card, a SECURE DIGITAL drive, or another suitable computer-readable storage medium or a combination of two or more of these, where appropriate. A computer-readable non-transitory storage medium may be volatile, nonvolatile, or a combination of volatile and non-volatile, as appropriate.

Certain embodiments have also been described herein with reference to block illustrations of methods, systems, and computer program products. It will be understood that blocks and/or combinations of blocks in the illustrations, as well as methods or steps or acts or processes described herein, can be implemented by a computer program comprising a routine of set instructions stored in a machine-readable storage medium as described herein. These instructions may be provided to one or more processors of a general purpose computer, special purpose computer, or other programmable data processing apparatus (or a combination of devices and circuits) to produce a machine, such that the instructions of the machine, when executed by the processor, implement the functions specified in the block or blocks, or in the acts, steps, methods and processes described herein.

These processor-executable instructions may also be stored in computer-readable memory that can direct a computer or other programmable data processing apparatus to function in a particular manner, such that the instructions stored in the computer-readable memory result in an article of manufacture including instructions which implement the function specified. The computer program instructions may also be loaded onto a computer or other programmable data processing apparatus to cause a series of operational steps to be performed on the computer or other programmable apparatus to realize a computer implemented process such that the instructions which execute on the computer or other programmable apparatus provide steps for implementing the functions specified in flowchart blocks that may be described herein.

In this regard, FIG. 23 illustrates one example of a computer system 2300 that can be employed to execute one or more embodiments of the present disclosure. Computer system 2300 can be implemented on one or more general purpose networked computer systems, embedded computer systems, routers, switches, server devices, client devices, various intermediate devices/nodes or standalone computer systems. Additionally, computer system 2300 can be implemented on various mobile clients such as, for example, a personal digital assistant (PDA), laptop computer, pager, and the like, provided it includes sufficient processing capabilities.

Computer system 2300 includes processing unit 2302, system memory 2304, and system bus 2306 that couples various system components, including the system memory 2304, to processing unit 2302. System memory 2304 can include volatile (e.g. RAM, DRAM, SDRAM, Double Data Rate (DDR) RAM, etc.) and non-volatile (e.g. Flash, NAND, etc.) memory. Dual microprocessors and other multi-processor architectures also can be used as processing unit 2302. System bus 2306 may be any of several types of bus structure including a memory bus or memory controller, a peripheral bus, and a local bus using any of a variety of bus architectures. System memory 2304 includes read only memory (ROM) 2310 and random access memory (RAM) 2312. A basic input/output system (BIOS) 2314 can reside in ROM 2310 containing the basic routines that help to transfer information among elements within computer system 2300.

Computer system 2300 can include a hard disk drive 2316, magnetic disk drive 2318, e.g., to read from or write to removable disk 2320, and an optical disk drive 2322, e.g., for reading CD-ROM disk 2324 or to read from or write to other optical media. Hard disk drive 2316, magnetic disk drive 2318, and optical disk drive 2322 are connected to system bus 2306 by a hard disk drive interface 2326, a magnetic disk drive interface 2328, and an optical drive interface 2330, respectively. The drives and associated computer-readable media provide nonvolatile storage of data, data structures, and computer-executable instructions for computer system 2300. Although the description of computer-readable media above refers to a hard disk, a removable magnetic disk and a CD, other types of media that are readable by a computer, such as magnetic cassettes, flash memory cards, digital video disks and the like, in a variety of forms, may also be used in the operating environment; further, any such media may contain computer-executable instructions for implementing one or more parts of embodiments shown and described herein.

A number of program modules may be stored in drives and RAM 2310, including operating system 2332, one or more application programs 2334, other program modules 2336, and program data 2338. In some examples, the application programs 2334 can include one or more modules configured to generate and transmit graphical content, such as an eyeline tool module, a teleprompter module, and a VFX tracking tool module. The program data 2338 can include the generated graphical content 112, such as eye and facial representations or unique visual markers. The application programs 2334 and program data 2338 can include functions and methods programmed to generate, transmit, and render graphical content on one or more display devices deployed in a production environment, and to coordinate the display of that graphical content across a plurality of display devices in real time in response to the requirements of a production workflow, such as shown and described herein.

A user may enter commands and information into computer system 2300 through one or more input devices 2340, such as a pointing device (e.g., a mouse, touch screen), keyboard, microphone, joystick, game pad, scanner, and the like. For instance, the user can employ input device 2340 to edit or modify the graphical content 112 transmitted to one or more of the plurality of display devices 2108a-n, including adjusting the scrolling speed, font size, or content of teleprompter text rendered on the display screens 2112a-n, updating the eye representations or gaze direction indicators rendered in the eyeline tool embodiment, selecting or modifying the unique visual markers rendered on the display screens 2112a-n in the VFX tracking tool embodiment, or updating the directional indicators, color-coded signals, or alphanumeric text rendered in the direction aid embodiment. These and other input devices 2340 are often connected to processing unit 2302 through a corresponding port interface 2342 that is coupled to the system bus, but may be connected by other interfaces, such as a parallel port, serial port, or universal serial bus (USB). One or more output devices 2344 (e.g., display, a monitor, printer, projector, or other type of displaying device) is also connected to system bus 2306 via interface 2346, such as a video adapter.

Computer system 2300 may operate in a networked environment using logical connections to one or more remote computers, such as remote computer 2348. Remote computer 2348 may be a workstation, computer system, router, peer device, or other common network node, and typically includes many or all the elements described relative to computer system 2300. The logical connections, schematically indicated at 2350, can include a local area network (LAN) and/or a wide area network (WAN), or a combination of these, and can be in a cloud-type architecture, for example configured as private clouds, public clouds, hybrid clouds, and multi-clouds. When used in a LAN networking environment, computer system 2300 can be connected to the local network through a network interface or adapter 2352. When used in a WAN networking environment, computer system 2300 can include a modem, or can be connected to a communications server on the LAN. The modem, which may be internal or external, can be connected to system bus 2306 via an appropriate port interface. In a networked environment, application programs 2334 or program data 2338 depicted relative to computer system 2300, or portions thereof, may be stored in a remote memory storage device 2354.

Embodiments disclosed herein include:
A. A display device comprising: a housing having a central opening; a display screen disposed within the central opening of the housing and configured to render graphical content; a controller disposed within the housing and configured to provide the graphical content to the display screen; and at least one mount disposed on the housing and configured to mechanically couple the display device to production mounting equipment in a production environment.
B. A display system comprising: a computing system; and one or more display devices, each display device of comprising: a housing having a central opening; a display screen disposed within the central opening of the housing and configured to render graphical content; and a controller disposed within the housing and communicatively connected to the display screen, wherein the computing system is communicatively connected to each of the display devices and is configured to transmit graphical content to each respective display screen via the respective controller of each display device.
C. A method of deploying a display system in a production environment, the method comprising positioning at least one display device at a desired location within the production environment, each display device comprising a housing having a central opening, a display screen disposed within the central opening, and a controller disposed within the housing and communicatively connected to the display screen; establishing a communicative connection between a computing system and each of the at least one display device; generating, at the computing system, graphical content; and transmitting the graphical content from the computing system to each of the at least one display device via the communicative connection, such that the controller of each display device drives the respective display screen to render the graphical content.

Each of embodiments A through C may have one or more of the following additional elements in any combination: Element 1: wherein the at least one mount comprises a first mount disposed at a lower portion of the housing and a second mount disposed at an upper portion of the housing, opposite the first mount. Element 2: a third mounting point disposed on a back face of the housing, the third mounting point providing an additional point of mechanical attachment for securing the display device to the production mounting equipment. Element 3: wherein the at least one mount comprises a threaded female end configured to receive a complementary threaded fastener of the production mounting equipment. Element 4: wherein the housing comprises a front cover and a back cover, the front cover being removably secured to the back cover by a threaded connection comprising front threads on an inner circumferential surface of the front cover and back threads on an inner circumferential surface of the back cover.

Element 5: wherein the front cover includes a front face having a front diameter and a screen diameter, the screen diameter defining the central opening through which the display screen is visible, and a region between the screen diameter and the front diameter forming the front face of the housing surrounding the display screen. Element 6: an internal support disposed within the housing between the front cover and the back cover, the internal support comprising an outer ring, a plurality of inwardly extending structural members defining a central mounting region, and a plurality of locating features distributed about the outer ring and configured to receive the controller.

Element 7: wherein the controller is configured to receive graphical content from an external computing system and to drive the display screen to render the graphical content. Element 8: wherein the controller is communicatively connected to a wireless communication system configured to receive the graphical content from the external computing system. Element 9: at least one port disposed on an outer surface of the housing and communicatively connected to the controller via at least one extender, the at least one port configured to provide at least one of wired power delivery or wired data transfer between the display device and the external computing system.

Element 10: wherein one or more display devices are a plurality of display devices and the computing system is configured to transmit different graphical content to each respective display device of the plurality of display devices simultaneously. Element 11: wherein the graphical content transmitted by the computing system to one or more of the plurality of display devices comprises a representation of one or more eyes configured to assist an actor with visualizing a gaze direction, emotional state, or spatial position of a computer-generated character. Element 12: wherein the computing system is configured to transmit graphical content corresponding to a first eye of a computer-generated character to a first display device of the plurality of display devices and graphical content corresponding to a second eye of the computer-generated character to a second display device of the plurality of display devices, such that a spatial separation between the first display device and the second display device replicates an interpupillary distance of the computer-generated character.

Element 13: wherein the graphical content transmitted by the computing system to one or more of the display devices comprises scrolling or static text configured to be rendered on the respective display screen. Element 14: herein the graphical content transmitted by the computing system to one or more of the display devices comprises a unique visual marker configured to be detected by one or more image sensors of one or more cameras present in a production environment, each unique visual marker serving as a spatial anchor enabling the computing system to establish and maintain a shared coordinate system across all devices in the production environment. Element 15: wherein the graphical content transmitted by the computing system to one or more of the display devices comprises at least one of a color-coded indicator, a directional arrow, a waypoint indicator, or alphanumeric text configured to communicate instructions, directions, or status information to personnel in a production environment, and wherein the computing system is configured to update the graphical content transmitted to any of the plurality of display devices in real time via a wireless communicative connection without requiring physical access to any individual display device.

Element 16: further comprising updating, at the computing system, the graphical content transmitted to one or more of the at least one display device in real time in response to at least one of a change in a production workflow, a change in a mode of operation, or an instruction received from an operator. Element 17: wherein positioning the at least one display device comprises mechanically coupling each display device to a production mounting equipment via at least one mount disposed on the housing of each display device, and wherein establishing the communicative connection comprises at least one of connecting a wired cable to a port disposed on an outer surface of the housing of each display device or wirelessly pairing each display device with the computing system.

By way of non-limiting example, exemplary combinations applicable to A through C include: Element 1 with Element 2; Element 4 with Element 5; Element 4 with Element 6; Element 7 with Element 8; Element 7 with Element 9; and Element 11 with Element 12.

Although this disclosure includes a detailed description on a computing platform and/or computer, implementation of the teachings recited herein are not limited to only such computing platforms. Rather, embodiments of the present disclosure are capable of being implemented in conjunction with any other type of computing environment now known or later developed.

Cloud computing is a model of service delivery for enabling convenient, on-demand network access to a shared pool of configurable computing resources (e.g., networks, network bandwidth, servers, processing, memory, storage, applications, virtual machines, and services) that can be rapidly provisioned and released with minimal management effort or interaction with a provider of the service. This cloud model may include at least five characteristics, at least three service models (e.g., software as a service (SaaS, platform as a service (PaaS), and/or infrastructure as a service (IaaS)) and at least four deployment models (e.g., private cloud, community cloud, public cloud, and/or hybrid cloud). A cloud computing environment can be service oriented with a focus on statelessness, low coupling, modularity, and semantic interoperability.

The present disclosure may be a system, a method, and/or a computer program product at any possible technical detail level of integration. The computer program product may include a computer readable storage medium (or media) having computer readable program instructions thereon for causing a processor to carry out aspects of the present disclosure. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware based systems that perform the specified functions or acts or carry out combinations of special purpose hardware and computer instructions.

The terminology used herein is for the purpose of describing particular embodiments only and is not intended to be limiting of the disclosure. As used herein, for example, the singular forms “a,” “an,” and “the” are intended to include the plural forms as well, unless the context clearly indicates otherwise. It will be further understood that the terms “contains”, “containing”, “includes”, “including,” “comprises”, and/or “comprising,” and variations thereof, when used in this specification, specify the presence of stated features, integers, steps, operations, elements, and/or components, but do not preclude the presence or addition of one or more other features, integers, steps, operations, elements, components, and/or groups thereof.

Terms of orientation used herein are merely for purposes of convention and referencing and are not to be construed as limiting. However, it is recognized these terms could be used with reference to an operator or user. Accordingly, no limitations are implied or to be inferred. In addition, the use of ordinal numbers (e.g., first, second, third, etc.) is for distinction and not counting. For example, the use of “third” does not imply there must be a corresponding “first” or “second.” Also, if used herein, the terms “coupled” or “coupled to” or “connected” or “connected to” or “attached” or “attached to” may indicate establishing either a direct or indirect connection, and is not limited to either unless expressly referenced as such. Furthermore, to the extent that the terms “includes,” “has,” “possesses,” and the like are used in the detailed description, claims, appendices and drawings such terms are intended to be inclusive in a manner similar to the term “comprising” as “comprising” is interpreted when employed as a transitional word in a claim. The term “based on” means “based at least in part on.” The terms “about” and “approximately” can be used to include any numerical value that can vary without changing the basic function of that value. When used with a range, “about” and “approximately” also disclose the range defined by the absolute values of the two endpoints, e.g. “about 2 to about 4” also discloses the range “from 2 to 4.” Generally, the terms “about” and “approximately” may refer to plus or minus 5-10% of the indicated number.

While the disclosure has described several exemplary embodiments, it will be understood by those skilled in the art that various changes can be made, and equivalents can be substituted for elements thereof, without departing from the spirit and scope of the disclosure. In addition, many modifications will be appreciated by those skilled in the art to adapt a particular instrument, situation, or material to embodiments of the disclosure without departing from the essential scope thereof. Therefore, it is intended that the disclosure not be limited to the particular embodiments disclosed, or to the best mode contemplated for carrying out this disclosure, but that the disclosure will include all embodiments falling within the scope of the appended claims. Moreover, reference in the appended claims to an apparatus or system or a component of an apparatus or system being adapted to, arranged to, capable of, configured to, enabled to, operable to, or operative to perform a particular function encompasses that apparatus, system, or component, whether or not it or that particular function is activated, turned on, or unlocked, as long as that apparatus, system, or component is so adapted, arranged, capable, configured, enabled, operable, or operative.

The invention claimed is:

1. A display device comprising:
a housing having a central opening;
a display screen disposed within the central opening of the housing and configured to render graphical content;
a controller disposed within the housing and configured to provide the graphical content to the display screen; and
at least one mount disposed on the housing and configured to mechanically couple the display device to production mounting equipment in a production environment.

2. The display device of claim 1, wherein the at least one mount comprises a first mount disposed at a lower portion of the housing and a second mount disposed at an upper portion of the housing, opposite the first mount.

3. The display device of claim 2, further comprising a third mounting point disposed on a back face of the housing, the third mounting point providing an additional point of mechanical attachment for securing the display device to the production mounting equipment.

4. The display device of claim 1, wherein the at least one mount comprises a threaded female end configured to receive a complementary threaded fastener of the production mounting equipment.

5. The display device of claim 1, wherein the housing comprises a front cover and a back cover, the front cover being removably secured to the back cover by a threaded connection comprising front threads on an inner circumferential surface of the front cover and back threads on an inner circumferential surface of the back cover.

6. The display device of claim 5, wherein the front cover includes a front face having a front diameter and a screen diameter, the screen diameter defining the central opening through which the display screen is visible, and a region between the screen diameter and the front diameter forming the front face of the housing surrounding the display screen.

7. The display device of claim 5, further comprising an internal support disposed within the housing between the front cover and the back cover, the internal support comprising an outer ring, a plurality of inwardly extending structural members defining a central mounting region, and a plurality of locating features distributed about the outer ring and configured to receive the controller.

8. The display device of claim 1, wherein the controller is configured to receive graphical content from an external computing system and to drive the display screen to render the graphical content.

9. The display device of claim 8, wherein the controller is communicatively connected to a wireless communication system configured to receive the graphical content from the external computing system.

10. The display device of claim 8, further comprising at least one port disposed on an outer surface of the housing and communicatively connected to the controller via at least one extender, the at least one port configured to provide at least one of wired power delivery or wired data transfer between the display device and the external computing system.

11. A display system comprising:
a computing system; and
one or more display devices, each display device of comprising:
a housing having a central opening;
a display screen disposed within the central opening of the housing and configured to render graphical content; and
a controller disposed within the housing and communicatively connected to the display screen, wherein the computing system is communicatively connected to each of the display devices and is configured to transmit graphical content to each respective display screen via the respective controller of each display device.

12. The display system of claim 11, wherein one or more display devices are a plurality of display devices and the computing system is configured to transmit different graphical content to each respective display device of the plurality of display devices simultaneously.

13. The display system of claim 11, wherein the graphical content transmitted by the computing system to one or more of the plurality of display devices comprises a representation of one or more eyes configured to assist an actor with visualizing a gaze direction, emotional state, or spatial position of a computer-generated character.

14. The display system of claim 13, wherein the computing system is configured to transmit graphical content corresponding to a first eye of a computer-generated character to a first display device of the plurality of display devices and graphical content corresponding to a second eye of the computer-generated character to a second display device of the plurality of display devices, such that a spatial separation between the first display device and the second display device replicates an interpupillary distance of the computer-generated character.

15. The display system of claim 11, wherein the graphical content transmitted by the computing system to one or more of the display devices comprises scrolling or static text configured to be rendered on the respective display screen.

16. The display system of claim 11, wherein the graphical content transmitted by the computing system to one or more of the display devices comprises a unique visual marker configured to be detected by one or more image sensors of one or more cameras present in a production environment, each unique visual marker serving as a spatial anchor enabling the computing system to establish and maintain a shared coordinate system across all devices in the production environment.

17. The display system of claim 11, wherein the graphical content transmitted by the computing system to one or more of the display devices comprises at least one of a color-coded indicator, a directional arrow, a waypoint indicator, or alphanumeric text configured to communicate instructions, directions, or status information to personnel in a production environment, and wherein the computing system is configured to update the graphical content transmitted to any of the plurality of display devices in real time via a wireless communicative connection without requiring physical access to any individual display device.

18. A method of deploying a display system in a production environment, the method comprising:
positioning at least one display device at a desired location within the production environment, each display device comprising a housing having a central opening, a display screen disposed within the central opening, and a controller disposed within the housing and communicatively connected to the display screen;
establishing a communicative connection between a computing system and each of the at least one display device;
generating, at the computing system, graphical content; and
transmitting the graphical content from the computing system to each of the at least one display device via the communicative connection, such that the controller of each display device drives the respective display screen to render the graphical content.

19. The method of claim 18, further comprising updating, at the computing system, the graphical content transmitted to one or more of the at least one display device in real time in response to at least one of a change in a production workflow, a change in a mode of operation, or an instruction received from an operator.

20. The method of claim 18, wherein positioning the at least one display device comprises mechanically coupling each display device to a production mounting equipment via at least one mount disposed on the housing of each display device, and wherein establishing the communicative connection comprises at least one of connecting a wired cable to a port disposed on an outer surface of the housing of each display device or wirelessly pairing each display device with the computing system.
